(19) United States
(12) Patent Application Publication
(10) Pub. No.: US 2026/0118437 A1
(43) Pub. Date: Apr. 30, 2026

(54) SYSTEM AND METHOD FOR DETECTING A SOFT-SHORT IN A BATTERY

(71) Applicant: GM GLOBAL TECHNOLOGY OPERATIONS LLC, Detroit, MI (US)

(72) Inventors: Insu Chang, Troy, MI (US); Ibrahim Haskara, Macomb, MI (US); Michael P. Barker, Troy, MI (US); Wesley Gerard Zanardelli, Rochester, MI (US)

(73) Assignee: GM GLOBAL TECHNOLOGY OPERATIONS LLC, Detroit, MI (US)

(21) Appl. No.: 18/931,166

(22) Filed: Oct. 30, 2024

(51) Int. Cl. G01R 31/392; G01R 31/367; G01R 31/389

(52) U.S. Cl. CPC G01R 31/392; G01R 31/367; G01R 31/389

(57) ABSTRACT

A system, vehicle and methods for detecting a soft-short in a battery utilize one or both of a first algorithm and a second algorithm for measuring an impedance of the battery at N_{z} frequency points and at one or more voltages (such as by using electrochemical impedance spectroscopy), calculating one or more errors, determining a number of occurrences of one of the calculated errors being greater than a threshold error, and identifying the battery as having a soft-short if the number of occurrences is greater than a threshold value.

This disclosure relates to systems and methods for detecting a soft-short in a battery, such as a battery cell or cell group within a battery module or battery pack.

In devices which are powered by batteries, such as automotive vehicles and the like, prognostics for battery health play an important role in battery management. Electrochemical Impedance Spectroscopy (EIS) is a viable method for monitoring battery health. EIS may be used to stimulate a battery and measure voltage changes, which then allows for impedance analysis.

However, there is a lack of clarity regarding impedance data (e.g., effective frequency range, etc.) and the subsequent processing required to detect battery health anomalies, such as soft-shorts.

### SUMMARY

According to one embodiment, a method for detecting a soft-short in a battery includes: (i) measuring an impedance of the battery at N_{z} frequency points within a frequency range and at a selected voltage that is lower than a predetermined voltage level, thereby producing N_{z} respective measured impedances each having a respective real component; (ii) calculating a respective error for each of the N_{z} measured impedances by comparing the respective real component of each of the measured impedances with a respective reference impedance that is representative of a healthy battery, thereby producing N_{z} respective calculated errors; (iii) determining a number of occurrences of one of the N_{z} calculated errors being greater than a threshold error; and (iv) identifying the battery as having a soft-short if the number of occurrences is greater than a threshold value.

The measuring of the impedance at the N_{z} frequency points may be conducted using electrochemical impedance spectroscopy, and the frequency range may be approximately 0.01 to 1 Hz.

Each reference impedance may be: (i) an average real impedance component that is a proxy for the healthy battery; or (ii) a respective member of a set of real impedance components that are representative of the healthy battery. The average real impedance component may be obtained from an average of respective real components of respective impedances from two or more other batteries that are configured for use with the battery as measured at the selected voltage and within the frequency range. Each respective member of the set of real impedance components may correspond to a respective one of the N_{z} frequency points.

Each reference impedance may be obtained from a look-up table, and each of the measured impedances may have a respective imaginary component.

The predetermined voltage level may be defined as a voltage level below which the real component of the measured impedance for a soft-shorted battery differs substantially from the real component of the reference impedance for a healthy battery within the frequency range.

The impedance of the battery may be measured at the N_{z} frequency points at approximately the same temperature.

The battery may be a lithium ion battery, wherein the predetermined voltage level is approximately 3.5 volts.

According to another embodiment, a method for detecting a soft-short in a battery includes: (i) measuring an impedance of the battery at N_{z} frequency points within a frequency range and at respective main and alternative voltages that are each higher than a predetermined voltage level, thereby producing N_{z} pairs of respective measured main and alternative impedances each having a respective real component; (ii) calculating a respective measured impedance error for each of the N_{z} pairs by comparing the respective real component of the respective measured main impedance with the respective real component of the respective measured alternative impedance, thereby producing respective measured impedance errors; (iii) calculating a respective reference impedance error for each of the N_{z} pairs by comparing a respective real component of a respective main reference impedance that corresponds to the main voltage with a respective real component of a respective alternative reference impedance that corresponds to the alternative voltage, thereby producing N_{z} respective reference impedance errors (iv) calculating a respective error of the errors for each of the N_{z} pairs by dividing a difference between the respective measured impedance error and the respective reference impedance error by the respective reference impedance error, thereby producing N_{z} respective errors of the errors; (v) determining a number of occurrences of one of the N_{z} errors of the errors being greater than a maximum allowable error; and (vi) identifying the battery as having a soft-short if the number of occurrences is greater than a threshold value.

In this embodiment, the measuring of the impedance at the N_{z} frequency points may be conducted using electrochemical impedance spectroscopy, and the frequency range may be approximately 0.1 to 10 Hz.

At least one of the main and alternative reference impedances may be: (i) an average real impedance component that is a proxy for a healthy battery; or (ii) a respective member of a set of real impedance components that are representative of the healthy battery. The average real impedance component may be obtained from an average of respective real components of respective impedances from two or more other batteries within the battery, and each respective member of the set of real impedance components may correspond to a respective one of the N_{z} frequency points.

The predetermined voltage level may be defined as a voltage level below which the real component of the measured impedance for a soft-shorted battery differs substantially from the real component of the reference impedance for a healthy battery within the frequency range.

The main and alternative impedances may be measured at approximately the same temperature, and the battery may be a lithium ion battery, wherein the predetermined voltage level is approximately 3.5 volts.

According to yet another embodiment, a vehicle having on-board capability for detecting a soft-short in a battery includes a vehicle body operatively supporting a propulsion system, an electrical system, the battery and an electrochemical impedance spectroscopy (EIS) system, wherein the propulsion system, the battery and the EIS system are each operatively connected with the electrical system, and wherein the EIS system is configured for executing at least one of a first algorithm and a second algorithm. The first algorithm includes: (i) measuring an impedance of the battery at N_{z} frequency points within a frequency range and at a first voltage that is lower than a predetermined voltage level using the EIS system, thereby producing N_{z} respective measured first impedances each having a respective real component; (ii) calculating a respective primary error for each of the N_{z} measured first impedances by comparing the respective real component of each of the measured first impedances with a respective first reference impedance that is representative of a healthy battery, thereby producing N_{z} respective primary errors; (iii) determining a number of occurrences of one of the N_{z} primary errors being greater than a threshold error; and (iv) identifying the battery as having a soft-short if the number of occurrences is greater than a threshold value. The second algorithm includes: (v) measuring the impedance of the battery at N_{z} frequency points within the frequency range and at respective second and third voltages that are each higher than the predetermined voltage level using the EIS system, thereby producing N_{z} pairs of respective measured second and third impedances each having a respective real component; (vi) calculating a respective measured impedance error for each of the N_{z} pairs by comparing the respective real component of the respective measured second impedance with the respective real component of the respective measured third impedance, thereby producing N_{z} respective measured impedance errors; (vii) calculating a respective reference impedance error for each of the N_{z} pairs by comparing a respective real component of a respective second reference impedance that corresponds to the second voltage with a respective real component of a respective third reference impedance that corresponds to the third voltage, thereby producing N_{z} respective reference impedance errors; (viii) calculating a respective error of the errors for each of the N_{z} pairs by dividing a difference between the respective measured impedance error and the respective reference impedance error by the respective reference impedance error, thereby producing N_{z} respective errors of the errors; (ix) determining a number of occurrences of one of the N_{z} errors of the errors being greater than a maximum allowable error; and (x) identifying the battery as having a soft-short if the number of occurrences is greater than the threshold value.

The above features and advantages, and other features and advantages, of the present teachings are readily apparent from the following detailed description of some of the best modes and other embodiments for carrying out the present teachings, as defined in the appended claims, when taken in connection with the accompanying drawings.

### BRIEF DESCRIPTION OF THE DRAWINGS

FIG. 1 is a block diagram of a system for detecting a soft-short in a battery, operatively connected with a vehicle.

FIG. 2 is a block diagram of a vehicle having on-board capability for detecting a soft-short in a battery.

FIG. 3 is a graphic showing multiple voltage levels.

FIG. 4 is a block diagram of impedances and their respective real and imaginary components for a battery at three voltage levels.

FIG. 5 is a block diagram of the impedance and its real and imaginary components for a battery at a first voltage.

FIG. 6 is a block diagram of the impedances and their respective real and imaginary components for a battery at a main voltage and an alternative voltage.

FIG. 7 is a block diagram of the impedances and their respective real and imaginary components for a battery at a first voltage, a second voltage and a third voltage.

FIG. 8 is a graph of the imaginary component of impedance versus the real component of impedance for multiple frequencies and voltage levels.

FIG. 9 is a graph of the imaginary component of impedance versus the real component of impedance versus voltage at a single frequency for multiple voltage levels.

FIG. 10 is a graph of the imaginary component of impedance versus the real component of impedance versus voltage for multiple frequencies and voltage levels.

FIG. 11 is a graph of frequency versus the real component of impedance for multiple voltages within a low-to medium-voltage region.

FIG. 12 is a graph of frequency versus the real component of impedance at a given voltage within a low-voltage region for a healthy battery and a soft-shorted battery.

FIG. 13A is a graph of the error between the real components of impedance for the healthy battery and the soft-shorted battery of FIG. 12, versus frequency, where the real components of impedance for the healthy battery are used as a baseline.

FIG. 13B is a graph of the percent error of the plots shown in FIG. 13A, where the real components of impedance for the healthy battery are used as a baseline.

FIG. 14 is a graph of the imaginary component of impedance versus the real component of impedance for multiple voltages within a medium-to high-voltage region.

FIG. 15 is a graph of frequency versus the real component of impedance for multiple voltages within a medium-to high-voltage region.

FIG. 16A is a graph of the difference between the real component of measured impedance at a main voltage of 3.6 V and the real component of measured impedance at an alternative voltage of 4.0 V, versus frequency, for a healthy battery and for two soft-shorted (500 Ω and 1000 Ω) batteries.

FIG. 16B is a graph of the error of the errors between a measured impedance error and a reference impedance error, versus frequency, for the healthy battery and the two soft-shorted (500 Ω and 1000 Ω) batteries.

FIG. 16C is a graph of the percent error of the plots shown in FIG. 16B, where the reference impedance error is used as a baseline.

FIGS. 17A-C are graphs which correspond to the elements shown in FIGS. 16A-C, respectively, but using a main voltage of 3.6 V and an alternative voltage of 3.8 V.

FIGS. 18A-C are graphs which correspond to the elements shown in FIGS. 16A-C, respectively, but using a main voltage of 3.8 V and an alternative voltage of 4.0 V.

FIG. 19 is a flowchart for a first method for detecting a soft-short in a battery.

FIG. 20 is a table of measured impedances and their respective real and imaginary components for a battery, for N_{z} frequency points and at a first voltage.

FIG. 21 is a block diagram showing error calculations for the first method.

FIG. 22 is a table of reference impedances and their respective real and imaginary components for N_{z} frequency points and at a first voltage, a main voltage and an alternative voltage.

FIG. 23 is a block diagram of the impedance and its real and imaginary components for a healthy battery.

FIG. 24 is a table of members of a set of real impedance components for N_{z} frequency points.

FIG. 25 is a block diagram of multiple other batteries and their respective impedances and respective real and imaginary components.

FIG. 26 is a block diagram showing number of occurrence calculations for the first method.

FIG. 27 is a block diagram showing a determination of whether the number of occurrences exceeds a threshold value for the first, second and third methods.

FIG. 28 is a block diagram of the impedance and its real and imaginary components for a soft-shorted battery.

FIG. 29 is a flowchart for a second method for detecting a soft-short in a battery.

FIG. 30 is a table of measured impedances and their respective real and imaginary components for a battery, for N_{z} frequency points and at a main voltage and an alternative voltage.

FIG. 31 is a block diagram showing measured impedance error calculations for the second method.

FIG. 32 is a block diagram showing reference impedance error calculations for the second method.

FIG. 33 is a block diagram showing error of the errors calculations for the second and third methods.

FIG. 34 is a block diagram showing number of occurrence calculations for the second method.

FIG. 35 is a flowchart for a first method for detecting a soft-short in a battery.

FIG. 36 is a table of measured impedances and their respective real and imaginary components for a battery, for N_{z} frequency points and at a first voltage, a second voltage and a third voltage.

FIG. 37 is a table of reference impedances and their respective real and imaginary components for N_{z} frequency points and at a first voltage, a second voltage and a third voltage.

FIG. 38 is a block diagram showing primary error calculations for the third method.

FIG. 39 is a block diagram showing a first number of occurrence calculations for the third method.

FIG. 40 is a block diagram showing measured impedance error calculations for the third method.

FIG. 41 is a block diagram showing reference impedance error calculations for the third method.

FIG. 42 is a logic flow diagram for detecting a soft-short in a battery, according to a first algorithm.

FIG. 43 is a logic flow diagram for detecting a soft-short in a battery, according to a second algorithm.

### DETAILED DESCRIPTION

Referring now to the drawings, wherein like numerals indicate like parts in the several views, various embodiments of a method 100, 200, 300 for detecting a soft-short SS in a battery B, as well as a system 10 for detecting a soft-short SS in a battery B and a vehicle VEH having on-board capability for detecting a soft-short SS in a battery B, are shown and described herein.

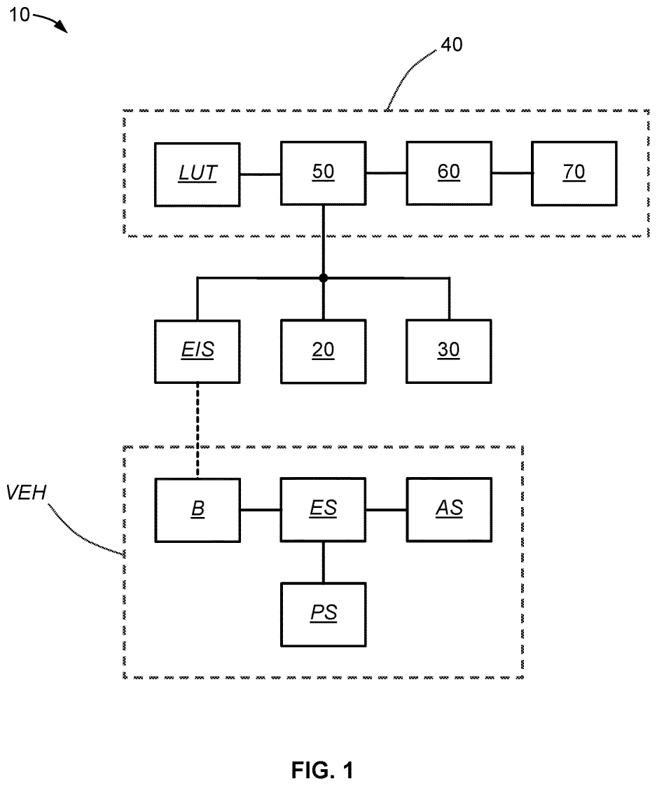

FIG. 1 shows a block diagram of a system 10 for detecting a soft-short SS in a battery B, operatively connected with a vehicle VEH. The vehicle VEH includes an electrical system ES, to which are connected a propulsion system PS, an electrical auxiliary system AS and a battery B. The system 10 includes an electrochemical impedance spectroscopy (EIS) system EIS which is configured for electrical connection with the battery B, and may further include an input system 20 (e.g., a keyboard, mouse, bar code scanner, radio frequency identification (RFID) scanner, etc.) and an output system 30 (e.g., a display monitor, a register address/flag, etc.). The EIS system EIS and the optional input/output systems 20, 30 may be connected with a controller or control system 40, which may include a processor 50, a memory 60 configured to contain instructions 70 (e.g., control code), and a look-up table LUT. In the arrangement shown, a vehicle VEH may be temporarily connected with the system 10 in order to detect whether the battery B in the vehicle VEH has a soft-short SS.

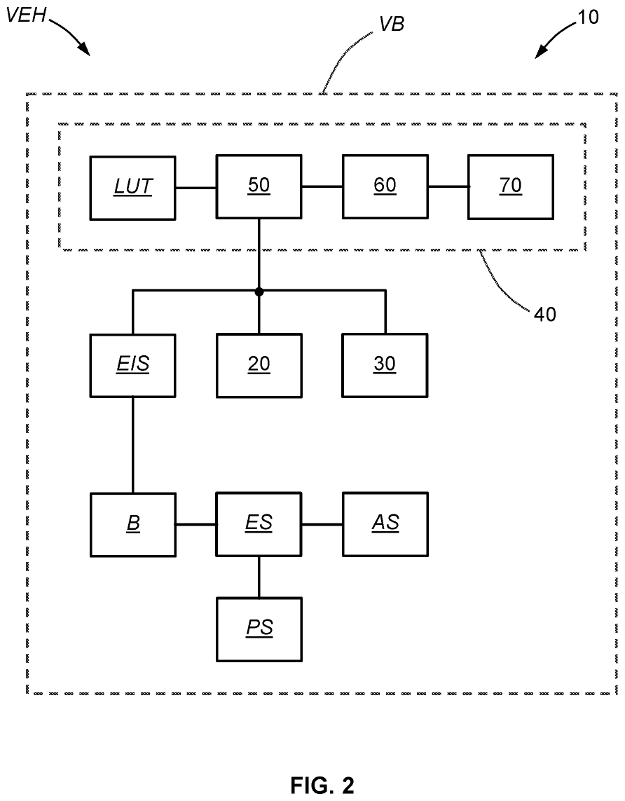

FIG. 2 shows a block diagram of a vehicle VEH having on-board capability for detecting a soft-short SS in the vehicle's battery B. Here, the vehicle VEH includes a vehicle body VB which supports, carries and/or houses an on-board system 10 similar to that shown in FIG. 1. Here, the on-board system 10 includes an EIS system EIS, an input system 20, an output system 40 and a controller/control system 40 which includes a processor 50, a memory 60 configured for storing instructions 70 and a look-up table LUT. The vehicle body VB further supports, carries and/or houses an electrical system ES to which are connected a propulsion system PS, an electrical auxiliary system AS and a battery B. In this arrangement, the battery B may be permanently connected with the EIS system EIS (e.g., in a constant monitoring arrangement) or the battery B may be intermittently/temporarily connected with the EIS system EIS whenever it is desired to determine whether the battery B may have a soft-short SS. Further, the vehicle VEH may be an automotive vehicle, such as a car, truck, boat, airplane, etc.

In either or both of the arrangements shown in FIGS. 1-2, the instructions 70 may include control code for causing the processor 50 and the EIS system EIS to execute one or more of a first algorithm or method 100, a second algorithm or method 200, and a third algorithm or method 300 for detecting a soft-short SS in the battery B.

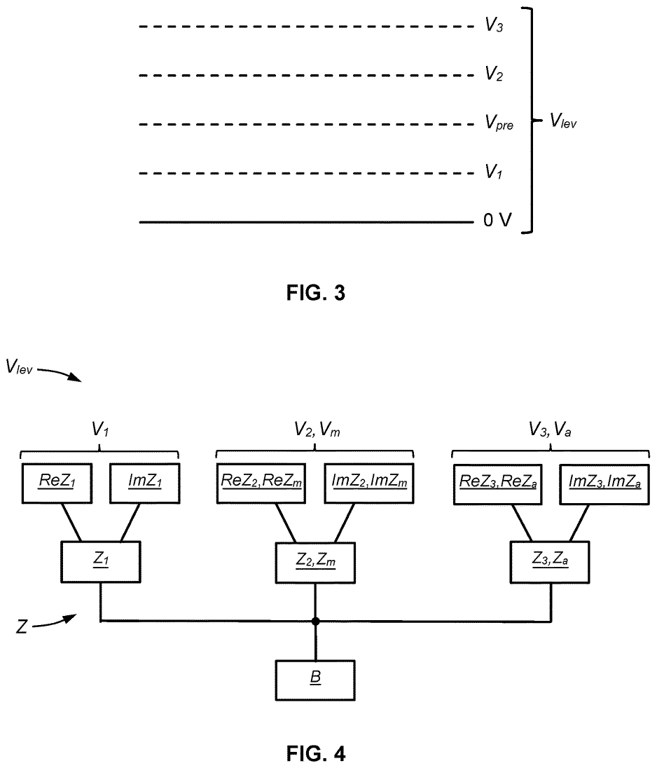

In general, the first algorithm or method 100 may be suitable for low-to medium-voltage regions or voltage levels, while the second algorithm or method 200 may be suitable for medium-to high-voltage regions or voltage levels. However, in some arrangements of battery type, battery chemistry, operating conditions, temperature ranges and the like, either of the two algorithms/methods 100, 200 may be suitable for any voltage region or voltage level Vₗₑᵥ. Thus, any statement herein that a given voltage region or voltage level Vₗₑᵥ may be suitable for use with one algorithm/method or another should not be construed as a requirement or limitation. For example, FIG. 3 shows various voltage levels Vₗₑᵥ, ranging from zero volts (0 V) to a first voltage V₁, a second voltage V₂ and a third voltage V₃, with a predetermined voltage level Vₚᵣₑ shown between the first and second voltages V₁, V₂. In some cases, the first algorithm or method 100 may be more suitable than the second algorithm or method 200 for voltage levels Vₗₑᵥ that are less than the predetermined voltage level Vₚᵣₑ (such as at the first voltage V₁), while the second algorithm or method 200 may be more suitable than the first algorithm or method 100 for voltage levels Vₗₑᵥ that are equal to or greater than the predetermined voltage level Vₚᵣₑ (such as at the second and third voltage levels V₂, V₃).

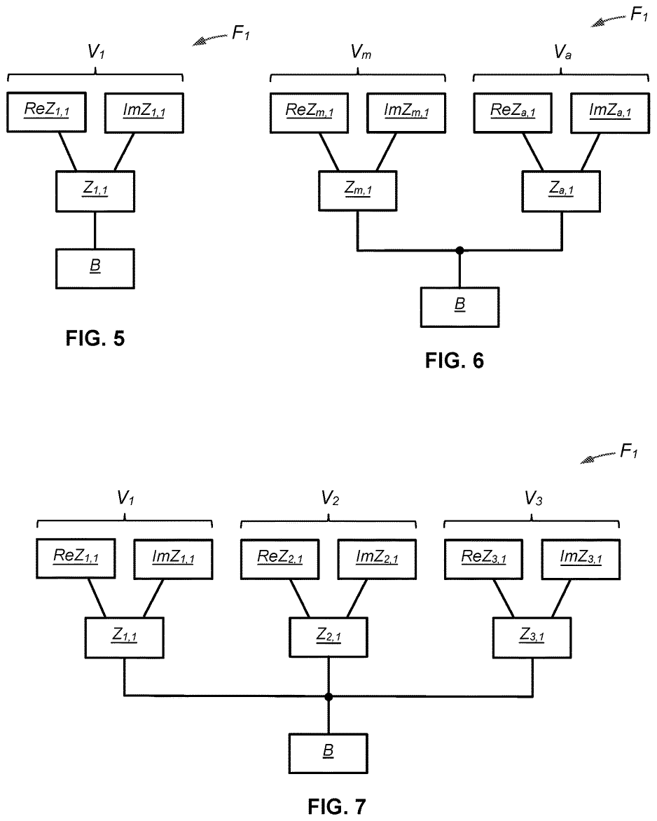

FIG. 4 shows a block diagram of impedances Z and their respective real and imaginary components ReZ, ImZ for a battery B at three different voltage levels Vₗₑᵥ; namely, at a first or selected voltage V₁, at a second or main voltage V₂, Vₘ, and at a third voltage or alternative voltage V₃, Vₐ. (As used herein, the second and main voltages V₂, Vₘ may be equivalent to each other, but they are given different names in order to distinguish their use in the first and second algorithms/methods 100, 200, respectively. Likewise, the third and alternative voltages V₃, Vₐ may be equivalent to each other, but they are given different names in order to distinguish their use in the first and second algorithms/methods 100, 200, respectively.) At the first voltage V₁, a first measured impedance Z₁ may be measured, which has a real component ReZ₁ and an imaginary component ImZ₁. At the second or main voltage V₂, Vₘ, a second or main measured impedance Z₂, Zₘ may be measured, which has a real component ReZ₂, ReZₘ and an imaginary component ImZ₂, ImZₘ. And at the third or alternative voltage V₃, Vₐ, a third or alternative measured impedance Z₃, Zₐ may be measured, which has a real component ReZ₃, ReZₐ and an imaginary component ImZ₃, ImZₐ. In any case, it may be noted that the impedance Z of a battery B is generally a function of battery chemistry, voltage V, temperature T and sometimes other factors, and that each impedance Z has a modulus—sometimes represented as “ModZ” (but not shown in the drawings)—where ModZ=sqrt [(ReZ)²+(ImZ)²]. (Thus, any calculation involving the modulus ModZ of an impedance Z will inherently involve the real component ReZ of the impedance Z.) FIG. 5 shows a block diagram of the impedance and its real and imaginary components for a battery B at a first voltage V₁ and at a first frequency point F₁. Here (and in FIGS. 6-7 to follow), the impedance and component names shown in FIG. 4 have been used, but a “1” subscript has been added so as to indicate that these particular impedances and components relate to the first frequency point F₁. As seen throughout the remainder of this description, as well as in the drawings, other subscripts may be appended to indicate impedances and components relating to other frequency points F, such as at the second frequency point F₂ (appending a “2” subscript), at an N_{z}^{th} frequency point F_{Nz} (appending an “Nz” subscript), and so forth. Thus, as shown here in FIG. 5, at the first voltage V₁ and first frequency point F₁, the battery B may have a first impedance Z_{1,1} having a real component ReZ_{1,1} and an imaginary component ImZ_{1,1}. (Here, the first “1” subscript indicates the first voltage V₁, and the second “1” subscript indicates the first frequency point F₁.) As explained further below, the subscripts and naming convention shown here in FIG. 5 relate to a first algorithm or method 100, as well as to a third algorithm or method 300 which utilizes elements of the first algorithm or method 100.

FIG. 6 is a block diagram of the impedances and their respective real and imaginary components for a battery B at a main voltage Vₘ and an alternative voltage Vₐ at a first frequency point F₁. Here, at the main voltage Vₘ, the battery B may have a main impedance Z_{m,1} having a real component ReZ_{m,1} and an imaginary component ImZ_{m,1}. (Here, the first “m” subscript indicates the main voltage Vₘ, and the second “1” subscript indicates the first frequency point F₁.) And at the alternative voltage Vₐ, the battery B may have an alternative impedance Z_{a,1} having a real component ReZ_{a,1} and an imaginary component ImZ_{a,1}. (Here, the first “a” subscript indicates the alternative voltage Vₐ, and the second “1” subscript indicates the first frequency point F₁.) As explained further below, the subscripts and naming convention shown here in FIG. 6 relate to a second algorithm or method 200.

FIG. 7 is a block diagram of the impedances and their respective real and imaginary components for a battery B at a first voltage V₁, a second voltage V₂ and a third voltage V₃ at a first frequency point F₁. Here, at the first voltage V₁, the battery B may have a first impedance Z_{1,1} having a real component ReZ_{1,1} and an imaginary component ImZ_{1,1}. (Here, the first “1” subscript indicates the first voltage V₁, and the second “1” subscript indicates the first frequency point F₁.) At the second voltage V₂, the battery B may have a second impedance Z_{2,1} having a real component ReZ_{2,1} and an imaginary component ImZ_{2,1}. (Here, the first “2” subscript indicates the second voltage V₂, and the second “1” subscript indicates the first frequency point F₁.) And at the third voltage V₃, the battery B may have a third impedance Z_{3,1} having a real component ReZ_{3,1} and an imaginary component ImZ_{3,1}. (Here, the first “3” subscript indicates the third voltage V₃, and the second “1” subscript indicates the first frequency point F₁.) As explained further below, the subscripts and naming convention shown here in FIG. 7 relate to a third algorithm or method 300, which utilizes elements of the first algorithm or method 100 and the second algorithm or method 200.

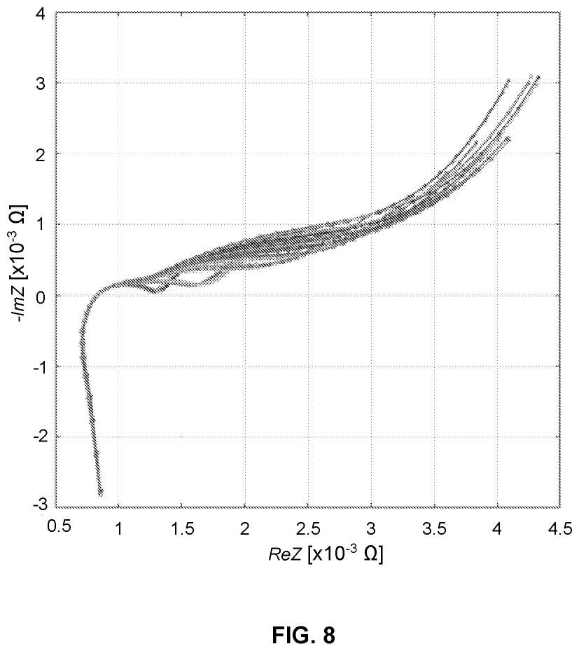

FIGS. 8-18C which follow show various impedance, voltage and frequency plots which may be measured on a battery B by an EIS system EIS. More specifically, the battery B that was measured in these plots was a lithium ion battery LIB configured for use in an electric automotive vehicle in a normal operating temperature environment and at a nominal state-of-charge.

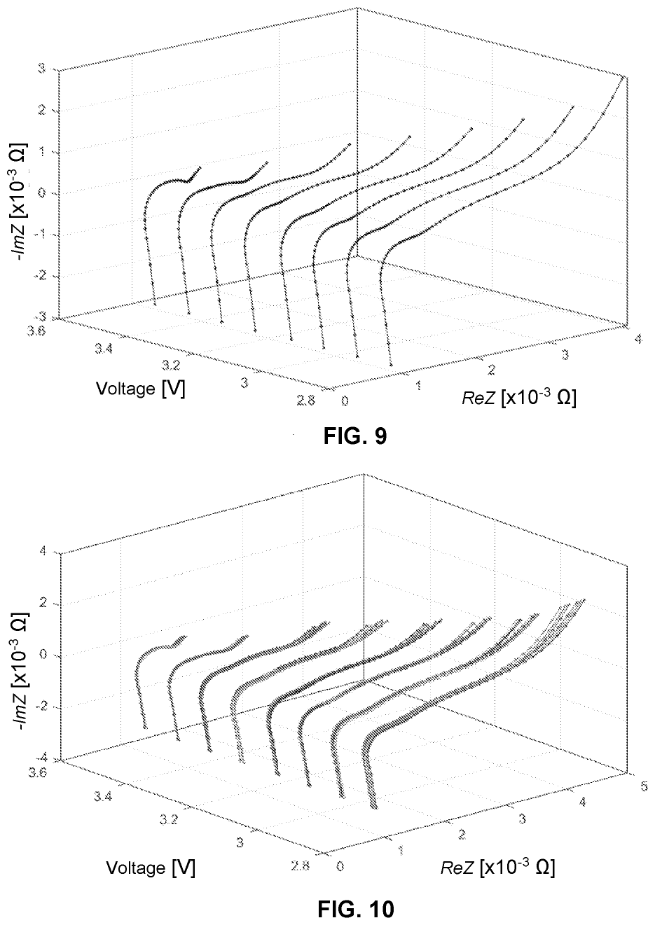

FIG. 8 shows a graph of the negative imaginary component of impedance-ImZ versus the real component of impedance ReZ, both measured in ohms (Ω), for multiple frequencies (measured in Hertz (Hz)) and voltages (measured in volts (V)). Note that the plots for the multiple frequencies and voltages appear to somewhat overlap one another in this view. However, FIGS. 9-10 show similar information as FIG. 8, but add an additional or third dimension (i.e., voltage) which permits the plots to be seen more clearly. Specifically, FIG. 9 shows the negative imaginary component of impedance −ImZ versus the real component of impedance ReZ versus voltage, for eight discrete voltages and for a single battery B, while FIG. 10 shows the same view as FIG. 9 but for multiple batteries B.

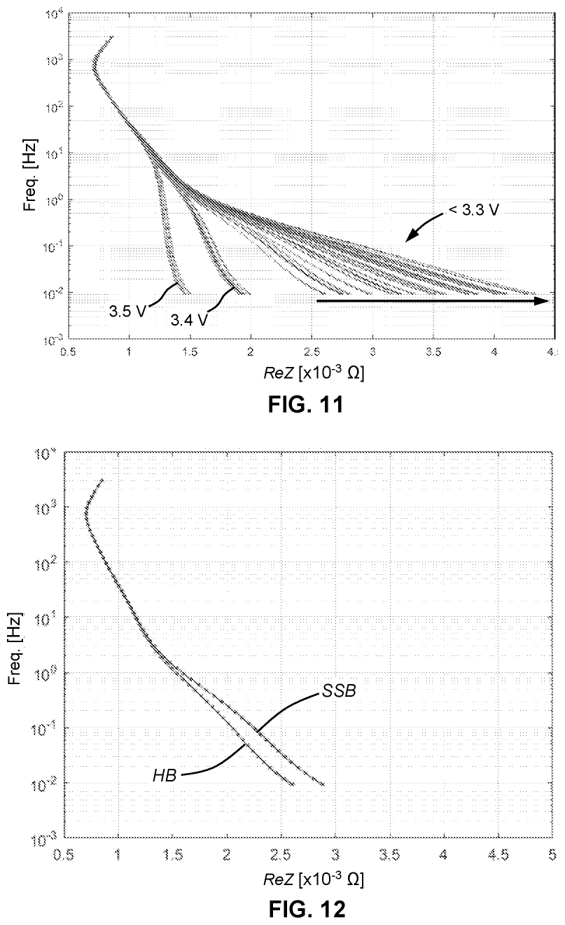

FIG. 11 shows a graph of frequency (Freq.) versus the real component of impedance ReZ for multiple voltages within a low-to medium-voltage region, such as may be suitable for use with the first algorithm or method 100. The plots are shown from 10⁻² Hz to about 3×10³ Hz, but note how the plots spread out more in the frequency range FR of 10⁻² to 10⁰ Hz (i.e., 0.01 to 1 Hz) for voltages below about 3.4 V (such as the 3.3 V and lower region). That is, for the given battery temperature and state of charge, the impedance of this lithium ion battery LIB exhibits a wide range of values in a low-voltage region of less than about 3.4 to 3.5 V.

FIG. 12 is a graph of frequency versus the real component of impedance ReZ at a voltage of 3.3 V for a healthy battery HB (i.e., one having no soft-shorts SS) and for a soft-shorted battery SSB (at 1000Ω). Similar to FIG. 11, the plots here are shown from 10⁻² Hz to about 3×10³ Hz, but note how the HB and SSB plots begin to spread apart from each other at about 10⁰ Hz (i.e., 1 Hz), and further spread apart from each other down through 10⁻² Hz (0.01 Hz), thus over a frequency range FR of about 10⁻² to 10⁰ Hz (i.e., about 0.01 to 1 Hz). If one were to examine plots similar to FIG. 12 but for voltages greater than the 3.3 V measured here, such as for 3.4 to 3.5 V and higher, one would see that over the frequency range FR of 10⁻² to 10⁰ Hz, the HB and SSB plots do not spread apart from each other as much as they do for voltages less than about 3.4 to 3.5 V. This voltage level of about 3.4 to 3.5 V may be defined as a predetermined voltage level Vₚᵣₑ, below which the real component of the measured impedance for a soft-shorted battery SSB deviates and differs substantially from the real component of the reference impedance for a healthy battery HB within the frequency range FR.

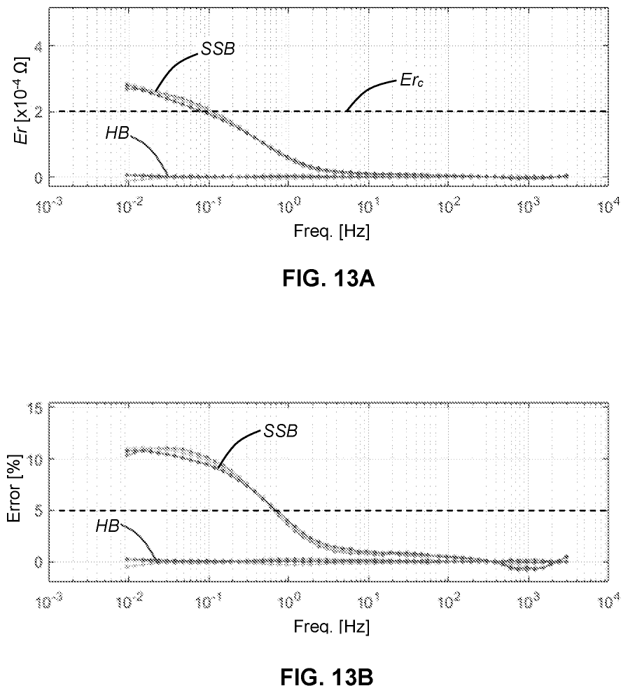

FIG. 13A is a graph of the error Er between the real components of impedance ReZ for the healthy battery HB and the soft-shorted battery SSB of FIG. 12, versus frequency, where the real components of impedance ReZ for the healthy battery HB are used as a baseline. FIG. 13A also includes a dashed horizontal line which shows a threshold error Er_{c}, which is explained further below. Relatedly, FIG. 13B shows a graph of the percent error of the plots shown in FIG. 13A, where the real components of impedance ReZ for the healthy battery HB are used as a baseline (i.e., the error Er of the SSB plot is divided by the amount of the HB plot). Like FIG. 13A, FIG. 13B also includes a dashed horizontal line, which may optionally be used as a threshold, as described further below.

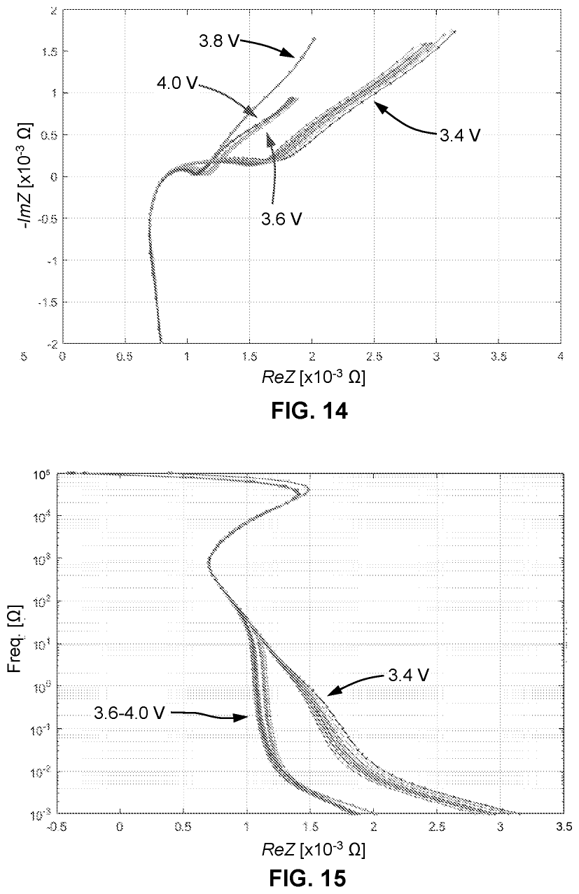

FIG. 14 shows a graph of the negative imaginary component of impedance −ImZ versus the real component of impedance ReZ for multiple voltages within a medium- to high-voltage region, and FIG. 15 shows a graph of frequency versus the real component of impedance ReZ for multiple voltages within a medium- to high-voltage region.

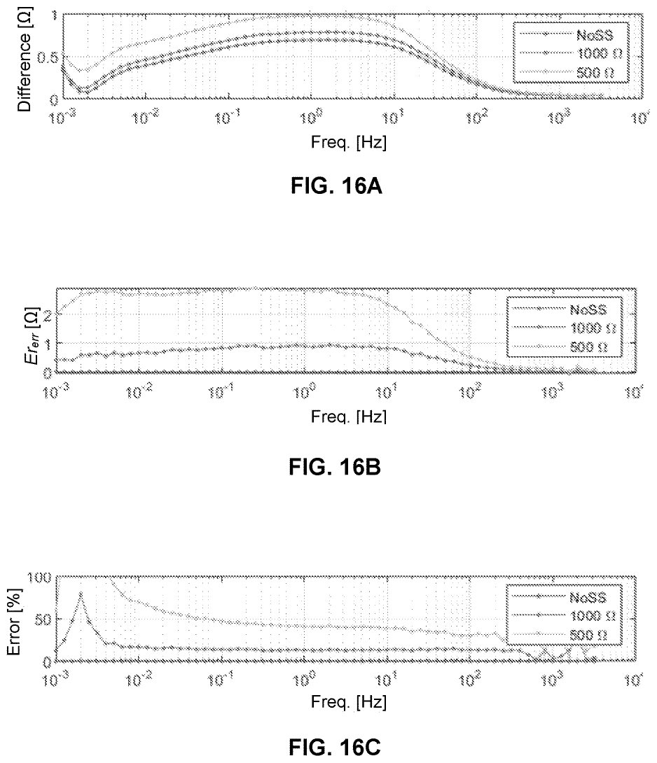

FIG. 16A shows a graph of the difference between the real component of measured impedance ReZ at a main voltage Vₘ of 3.6 V and the real component of measured impedance ReZ at an alternative voltage Vₐ of 4.0 V, versus frequency, for a healthy battery HB (designated as “NoSS” in the drawings, for “no soft-short”) and for two soft-shorted batteries SSB (at 500 Ω and 1000 Ω). Relatedly, FIG. 16B shows a graph of the error of the errors Erₑᵣᵣ between a measured impedance error Erₘₑₐₛ and a reference impedance error Er_{ref}, versus frequency, for the healthy battery HB and the two soft-shorted batteries SSB (at 500 Ω and 1000 Ω), and FIG. 16C shows a graph of the percent error of the plots shown in FIG. 16B, where the reference impedance error Er_{ref} is used as a baseline.

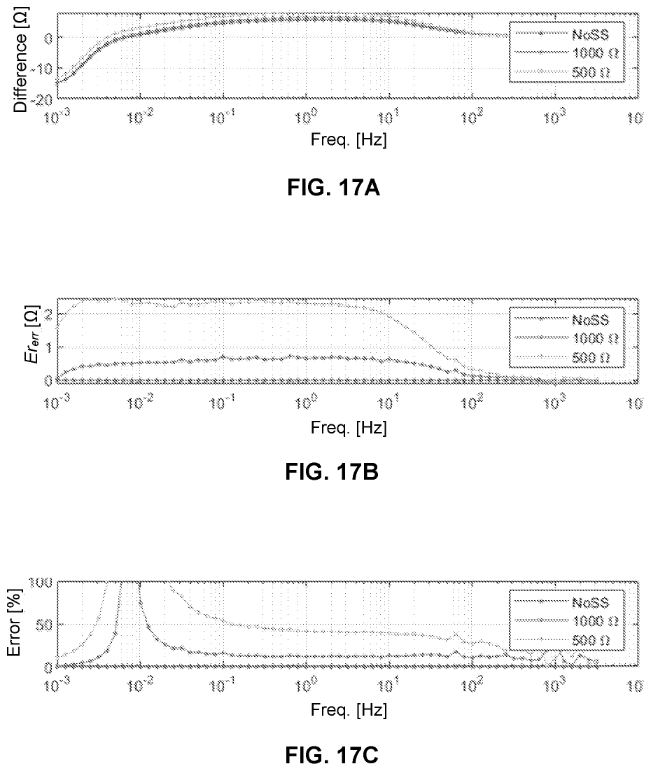

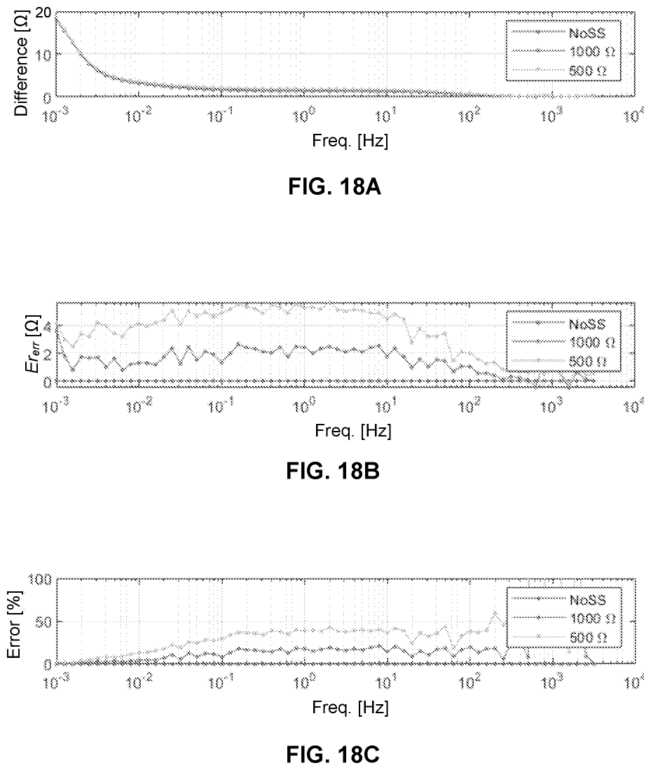

FIGS. 17A-C are graphs which correspond to the elements shown in FIGS. 16A-C, respectively, but using a main voltage Vₘ of 3.6 V and an alternative voltage Vₐ of 3.8 V, and FIGS. 18A-C are graphs which also correspond to the elements shown in FIGS. 16A-C, respectively, but using a main voltage Vₘ of 3.8 V and an alternative voltage Vₐ of 4.0 V.

With the foregoing provided as background, the algorithms or methods 100, 200, 300, the system 10 and the vehicle VEH according to the present disclosure will now be described in detail.

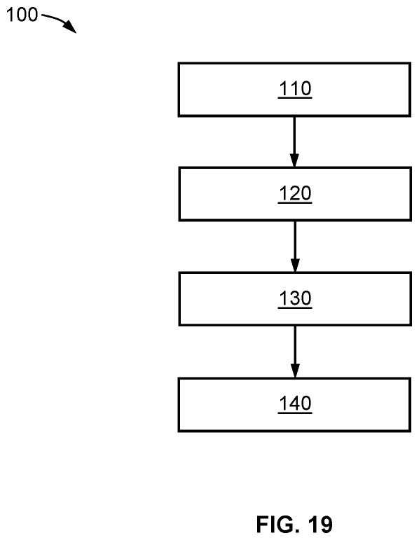

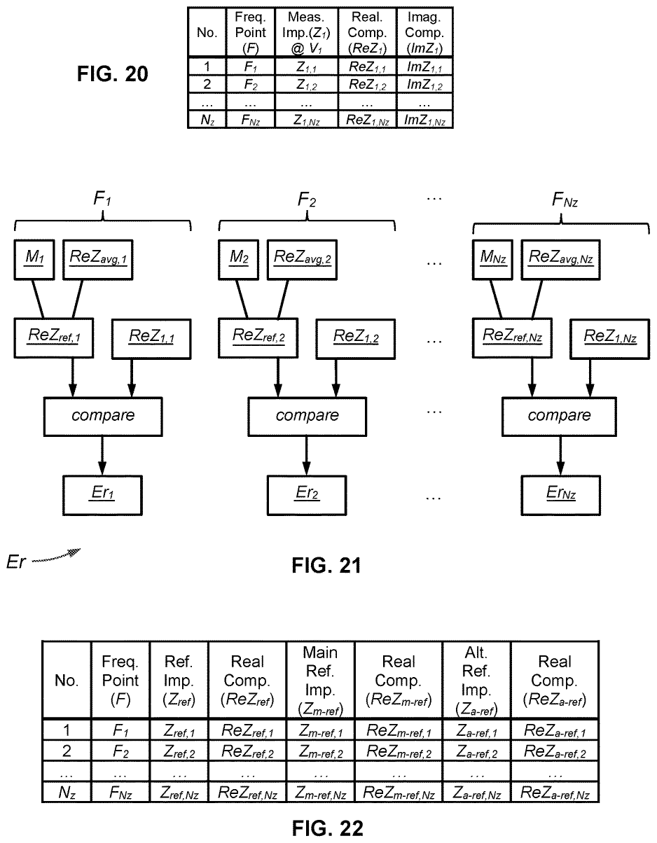

FIG. 19 shows a flowchart for the first algorithm or method 100. At block 110, an impedance Z of the battery B is measured (e.g., using an EIS system EIS) at N_{z} frequency points within a frequency range FR and at a selected or first voltage V₁ that is lower than a predetermined voltage level Vₚᵣₑ, thereby producing N_{z} respective measured impedances Z₁, with each measured impedance Z₁ having a respective real component ReZ₁ and a respective imaginary component ImZ₁. For example, if ten specific frequency points F are selected from within the frequency range FR (i.e., N_{z}=10), then the first frequency point F may be designated as F₁, the second frequency point F may be designated as F₂, and the tenth or N_{z}^{th} frequency point F may be designated as F_{Nz}. In this example, block 110 would produce ten measured impedances Z₁ (since N_{z}=10), which would include ten real components ReZ₁ and ten imaginary components ImZ₁. For example, see the table shown in FIG. 20, which shows the N_{z} frequency points F (i.e., F₁, F₂, . . . F_{Nz}), the N_{z} measured impedances Z₁ that are measured at the first voltage V₁ (i.e., Z_{1,1}, Z_{1,2}, . . . Z_{1,Nz}), and the respective real components ReZ₁ (i.e., ReZ_{1,1}, ReZ_{1,2}, . . . ReZ_{1,Nz}) and imaginary components ImZ₁ (i.e., ImZ_{1,1}, ImZ_{1,2}, . . . ImZ_{1,Nz}) of the N_{z} measured impedances Z₁.

Returning now to FIG. 19, at block 120, a respective error Er is calculated for each of the N_{z} measured impedances Z₁ by comparing the respective real component ReZ₁ of each of the measured impedances Z₁ with a respective reference impedance Z_{ref} that is representative of a healthy battery HB, thereby producing N_{z} respective calculated errors Er. This block 120 is further illustrated in the block diagram of FIG. 21 and in the first four columns of the table in FIG. 22. In FIG. 21, calculations are shown for the first frequency point F₁, the second frequency point F₂ and through to the N_{z}^{th} frequency point F_{NZ}. For example, for the first frequency point F₁, the real component ReZ_{1,1} of the first measured impedance Z_{1,1} is compared with (e.g., subtracted from) the real component ReZ_{ref,1} of the first instance of the reference impedance Z_{ref,1}, which yields a first calculated error Er₁. Similarly, for the second frequency point F₂, the real component ReZ_{1,2} of the second measured impedance Z_{1,2} is compared with (e.g., subtracted from) the real component ReZ_{ref,2} of the second instance of the reference impedance Z_{ref,2}, which yields a second calculated error Er₂, and for the N_{z}^{th} frequency point F_{Nz}, the real component ReZ_{1,Nz} of the N_{z}^{th} measured impedance Z_{1,Nz} is compared with (e.g., subtracted from) the real component ReZ_{ref,Nz} of N_{z}^{th} instance of the reference impedance Z_{ref,Nz}, which yields N_{z}^{th} calculated error Er_{Nz}.

In the table of FIG. 22, the first four columns relate to the various instances of the reference impedance Z_{ref} which may be used with the first algorithm or method 100 which utilizes the first voltage V₁. For the first frequency point F₁, the first instance of the reference impedance Z_{ref,1} has a first real component ReZ_{ref,1} (and a corresponding imaginary component that is not shown). Similarly, for the second frequency point F₂, the second instance of the reference impedance Z_{ref,2} has a second real component ReZ_{ref,2} (and a corresponding imaginary component that is not shown), and for the N_{z}^{th} frequency point F_{Nz}, the N_{z}^{th} instance of the reference impedance Z_{ref,Nz} has N_{z}^{th} real component ReZ_{ref,Nz} (and a corresponding imaginary component that is not shown).

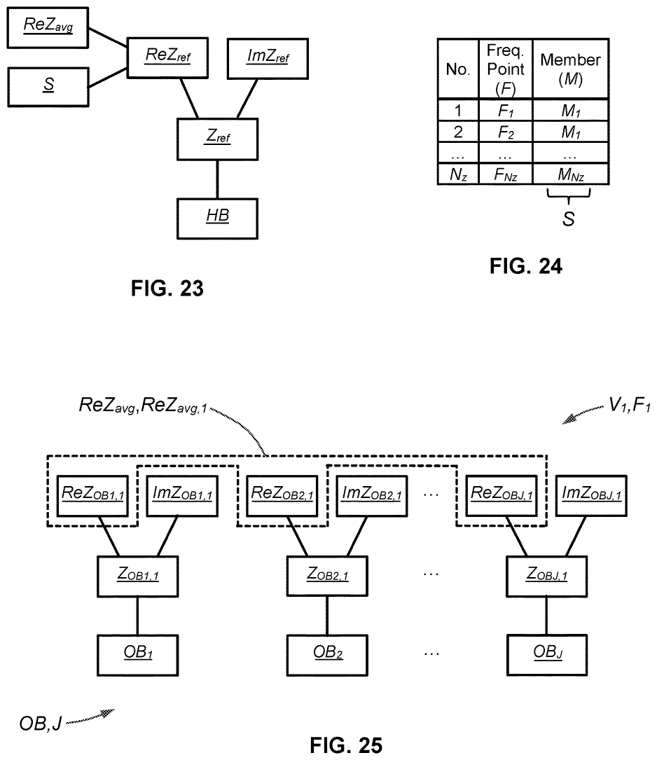

FIGS. 23-24 further elucidate the reference impedances Z_{ref}. As noted above, the reference impedances Z_{ref} are representative of a healthy battery HB, which is illustrated in FIG. 23. The healthy battery HB has a reference impedance Z_{ref} which has a real component ReZ_{ref} and an imaginary component ImZ_{ref}. Note that while FIG. 23 only shows a single reference impedance Z_{ref}, this is for the sake of brevity only, as in reality the healthy battery HB may have N_{z} individual reference impedances Z_{ref}—i.e., one for each of the N_{z} frequency points F. Additionally, note that FIG. 23 only shows the real component ReZ_{ref} for each frequency point F (i.e., the imaginary components ImZ_{ref} are not shown).

The reference impedances Z_{ref} may be actual measurements taken on a healthy battery HB at the various frequency points F and at the first voltage V₁ at a given temperature. Alternatively, as illustrated in FIGS. 23-24, the reference impedances Z_{ref} may be: (i) an average real impedance component ReZ_{avg} that is used as a proxy for the healthy battery HB; or (ii) a respective member M of a set S of real impedance components (i.e., M₁, M₂, . . . M_{Nz}) that are representative of the healthy battery HB, wherein each respective member M of the set S of real impedance components ReZ may correspond to a respective one of the N_{z} frequency points. Note that the average real impedance component ReZ_{avg} may be a single value that may be used for all of the frequency points F, or it may be an array of values (e.g., with a respective unique value assigned to each of the frequency points F).

FIG. 25 shows a block diagram of multiple other batteries OB and their respective impedances and respective real and imaginary components. These other batteries OB may be additional or other batteries besides the subject battery B being evaluated, such as other batteries that are in a battery pack with the subject battery B and are configured for use with the battery B. The drawing shows a first other battery OB₁, a second other battery OB₂, and up through a J^{th} other battery OB_{J}, with respective impedances Z_{OB1,1}, Z_{OB2,1}, . . . Z_{OBJ,1} and respective real components ReZ_{OB1,1}, ReZ_{OB2,1}, . . . ReZ_{OBJ,1} and imaginary components ImZ_{OB1,1}, ImZ_{OB2,1}, . . . ImZ_{OBJ,1} being determined at a first voltage V₁ and at a first frequency point F₁. The average real impedance component ReZ_{avg} may be obtained from an average of these real components ReZ_{OB1,1}, ReZ_{OB2,1}, . . . ReZ_{OBJ,1}. As noted above, average real impedance component ReZ_{avg} may be a single value which may be used for all of the frequency points F, or it may be an array of values with a respective unique value/average determined for each of the frequency points F. In any case, each reference impedance Z_{ref} may optionally be stored in and obtained from a look-up table LUT.

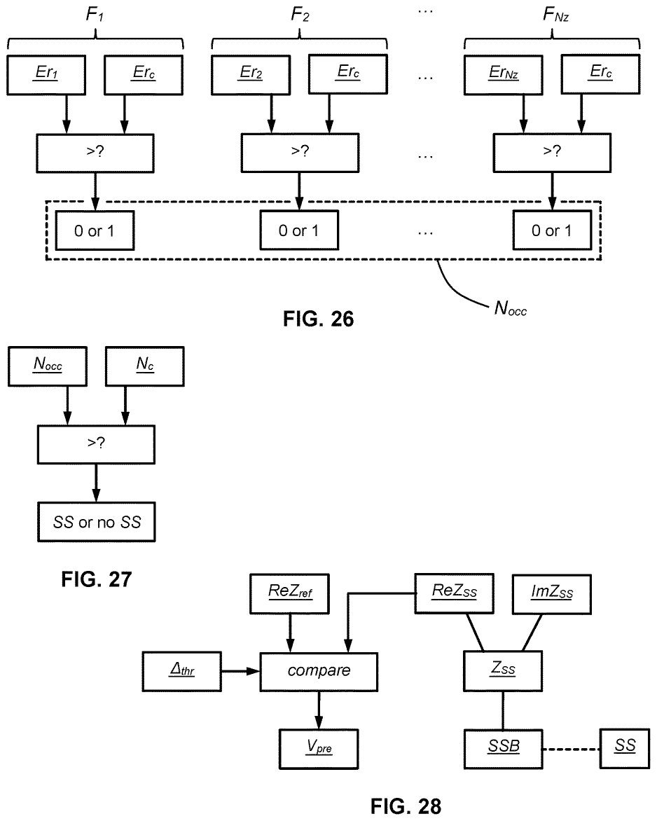

Returning again to FIG. 19, at block 130, a number of occurrences N_{occ} is determined for when any one of the N_{z} calculated errors Er is greater than a threshold error Er_{c}. This block 130 is further illustrated in the block diagram of FIG. 26, where calculations are shown for the first frequency point F₁, the second frequency point F₂ and through to the N_{z}^{th} frequency point F_{NZ}. For example, for the first frequency point F₁, the first calculated error Er₁ is compared with the threshold error Er_{c}, which yields either a zero (0) if the first calculated error Er₁ is not greater than the threshold error Er_{c}, or a one (1) if the first calculated error Er₁ is greater than the threshold error Er_{c}. Similarly, for the second frequency point F₂, the second calculated error Er₂ is compared with the threshold error Er_{c}, which yields either a zero (0) if the second calculated error Er₂ is not greater than the threshold error Er_{c} or a one (1) if the second calculated error Er₂ is greater than the threshold error Er_{c}, and for the N_{z}^{th} frequency point F_{Nz}, the N_{z}^{th} calculated error Er_{Nz} is compared with the threshold error Er_{c}, which yields either a zero (0) if the N_{z}^{th} calculated error Er_{Nz} is not greater than the threshold error Er_{c}, or a one (1) if the N_{z}^{th} calculated error Er_{Nz} is greater than the threshold error Er_{c}. The number of occurrences N_{occ} is then the sum of these zeroes and ones.

Finally, at block 140, and as illustrated in the block diagram of FIG. 27, the battery B is identified as having a soft-short SS if the number of occurrences N_{occ} is greater than a threshold value N_{c}. As shown in the drawing, if the number of occurrences N_{occ} is greater than the threshold value N_{c}, then the presence of a soft-short SS is determined; this may be indicated by a flag set in the memory 60, by reversing or changing a value (e.g., from 0 to 1) in a register, by turning on an indicator light or an audible alert, etc. However, if the number of occurrences N_{occ} is not greater than the threshold value N_{c}, then the absence of a soft-short SS is determined; this may be indicated by a flag set in the memory 60, by reversing or changing a value (e.g., from 1 to 0) in a register, by turning an indicator light or an audible alert on or off, etc.

The frequency range FR may be approximately 0.01 to 1 Hz, and the impedance Z of the battery B may be measured at the N_{z} frequency points at approximately the same temperature T.

FIG. 28 shows a block diagram of the impedance Z_{SS} for a soft-shorted battery SSB having a soft short SS, along with the impedance's real and imaginary components ReZ_{SS}, ImZ_{SS}. As mentioned above in connection with FIG. 12, and as illustrated in FIG. 28 as well, the predetermined voltage level Vₚᵣₑ may be defined as a voltage level Vₗₑᵥ below which the real component of the measured impedance for a soft-shorted battery SSB—i.e., ReZ_{SS}—differs substantially from the real component of the reference impedance for a healthy battery HB—i.e., ReZ_{ref}—within the frequency range FR. As shown in FIG. 28, a comparison is made between ReZ_{SS} and ReZ_{ref} to determine whether they differ from each other by more than a difference threshold Δₜₕᵣ. Optionally, the battery B may be a lithium ion battery LIB, wherein the predetermined voltage level Vₚᵣₑ is approximately 3.5 volts.

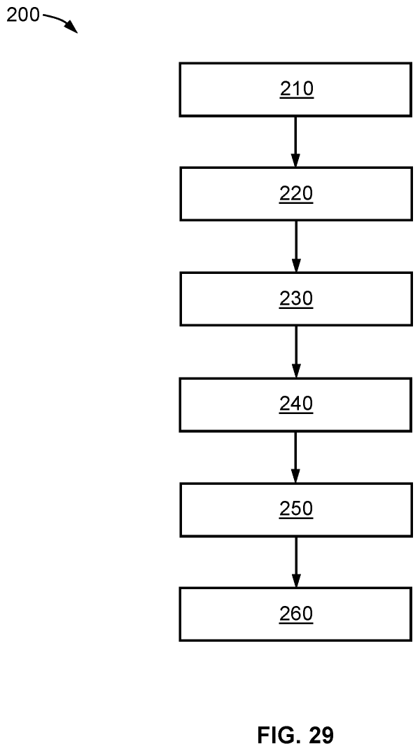

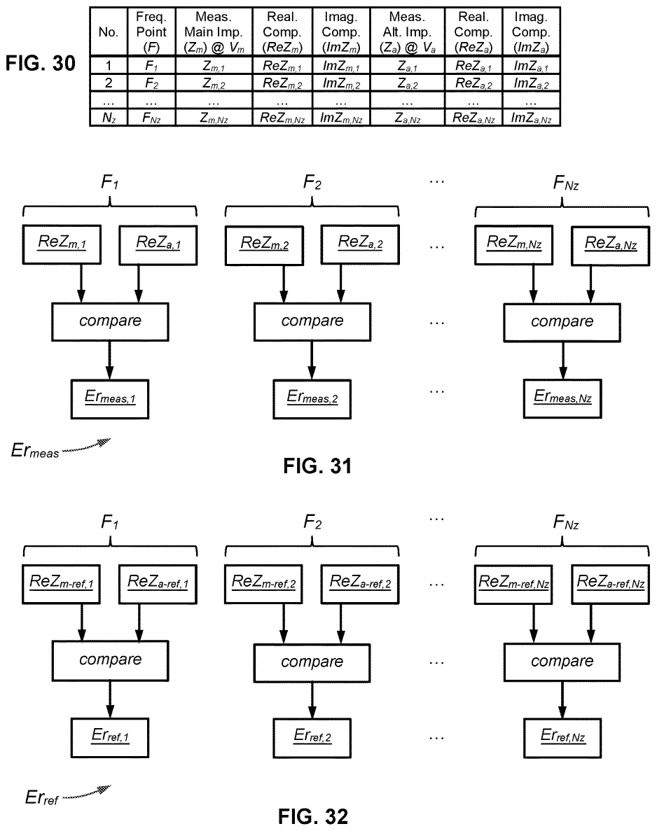

FIG. 29 shows a flowchart for the second algorithm or method 200. At block 210, an impedance Z of the battery B is measured at N_{z} frequency points within a frequency range FR and at respective main and alternative voltages Vₘ, Vₐ that are each higher than a predetermined voltage level Vₚᵣₑ. As illustrated in the table of FIG. 30, this measurement produces N_{z} pairs of respective measured main and alternative impedances Zₘ, Zₐ each having a respective real component ReZₘ, ReZₐ and a respective imaginary component ImZₘ, ImZₐ. For example, at a first frequency point F₁ within the frequency range FR, a first measured main impedance Z_{m,1} has respective first real and imaginary components ReZ_{m,1}, ImZ_{m,1}, and a first measured alternative impedance Z_{a,1} has respective first real and imaginary components ReZ_{a,1}, ImZ_{a,1}. Similarly, at a second frequency point F₂, a second measured main impedance Z_{m,2} has respective second real and imaginary components ReZ_{m,2}, ImZ_{m,2}, and a second measured alternative impedance Z_{a,2} has respective second real and imaginary components ReZ_{a,2}, ImZ_{a,2}, while at an N_{z}^{th} frequency point F_{Nz}, an N_{z}^{th} measured main impedance Z_{m,Nz} has respective N_{z}^{th} real and imaginary components ReZ_{m,Nz} ImZ_{m,Nz}, and an N_{z}^{th} measured Z_{a,Nz}native impedance Z_{a,Nz} has respective N_{z}^{th} real and imaginary components ReZ_{a,Nz} ImZ_{a,Nz}.

At block 220, a respective measured impedance error Erₘₑₐₛ is calculated for each of the N_{z} pairs by comparing the respective real component ReZₘ of the respective measured main impedance Zₘ with the respective real component ReZₐ of the respective measured alternative impedance Zₐ, thereby producing N_{z} respective measured impedance errors Erₘₑₐₛ. This block 220 is further illustrated in the block diagram of FIG. 31, where calculations are shown for the first frequency point F₁, the second frequency point F₂ and through to the N_{z}^{th} frequency point F_{NZ}. For example, for the first frequency point F₁, the real component ReZ_{m,1} of the first measured main impedance Z_{m,1} is compared with (e.g., subtracted from) the real component ReZ_{a,1} of the first measured alternative impedance Z_{a,1}, which yields a first measured impedance error Er_{meas,1}. Similarly, for the second frequency point F₂, the real component ReZ_{m,2} of the second measured main impedance Z_{m,2} is compared with (e.g., subtracted from) the real component ReZ_{a,2} of the second measured alternative impedance Z_{a,2}, which yields a second measured impedance error Er_{meas,2}, and for the N_{z}^{th} frequency point F_{Nz}, the real component ReZ_{m,Nz} of N_{z}^{th} measured main impedance Z_{m,Nz} is compared with (e.g., subtracted from) the real ReZ_{a,Nz}of the N_{z}^{th} measured alternative impedance Z_{a,Nz}, which yields N_{z}^{th} measured impedance error Er_{meas,Nz}.

At block 230, a respective reference impedance error Er_{ref} is calculated for each of the N_{z} pairs by comparing a respective real component ReZ_{m-ref} of a respective main reference impedance Z_{m-ref} that corresponds to the main voltage Vₘ with a respective real component ReZ_{a-ref} of a respective alternative reference impedance Z_{a-ref} that corresponds to the alternative voltage Vₐ, thereby producing N_{z} respective reference impedance errors Er_{ref}. This block 230 is further illustrated in the block diagram of FIG. 32 and in the first, second and fifth through eighth columns of the table in FIG. 22. In FIG. 32, calculations are shown for the first frequency point F₁, the second frequency point F₂ and through to the N_{z}^{th} frequency point F_{NZ}. For example, for the first frequency point F₁, the real component ReZ_{m-ref,1} of the first main reference impedance Z_{m-ref,1} is compared with (e.g., subtracted from) the real component ReZ_{a-ref,1} of the first alternative reference impedance Z_{a-ref,1}, which yields a first reference impedance error Er_{ref,1}. Similarly, for the second frequency point F₂, the real component ReZ_{m-ref,2} of the second main reference impedance Z_{m-ref,2} is compared with (e.g., subtracted from) the real component ReZ_{a-ref,2} of the second alternative reference impedance Z_{a-ref,2}, which yields a second reference impedance error Er_{ref,2}, and for the N_{z}^{th} frequency point F_{Nz}, the real component ReZ_{m-ref,Nz} of N_{z}^{th} main reference Z_{m-ref,Nz} is compared with (e.g., subtracted from) the real component ReZ_{a-ref,Nz} of N_{z}^{th} alternative reference impedance Z_{a-ref,Nz}, which yields N_{z}^{th} reference impedance error Er_{ref,Nz}.

In the table of FIG. 22, the first, second and fifth through eighth columns relate to the reference impedances Z_{ref} which may be used with the second algorithm or method 200 which utilizes the main and alternative voltages Vₘ, Vₐ. For the first frequency point F₁, the first main reference impedance Z_{m-ref,1} has a first real component ReZ_{m-ref,1} (and a corresponding imaginary component that is not shown), and the first alternative reference impedance Z_{a-ref,1} has a first real component ReZ_{a-ref,1} (and a corresponding imaginary component that is not shown). Similarly, for the second frequency point F₂, the second main reference impedance Z_{m-ref,2} has a second real component ReZ_{m-ref,2} (and a corresponding imaginary component that is not shown) and the second alternative reference impedance Z_{a-ref,2} has a second real component ReZ_{a-ref,2} (and a corresponding imaginary component that is not shown); and for the N_{z}^{th} frequency point F_{Nz}, the N_{z}^{th} main reference impedance Z_{m-ref,Nz} has an N_{z}^{th} real component ReZ_{m-ref,Nz} (and a corresponding imaginary component that is not shown) and the N_{z}^{th} alternative reference impedance Z_{a-ref,Nz} has N_{z}^{th} real component ReZ_{a-ref,Nz} (and a corresponding imaginary component that is not shown).

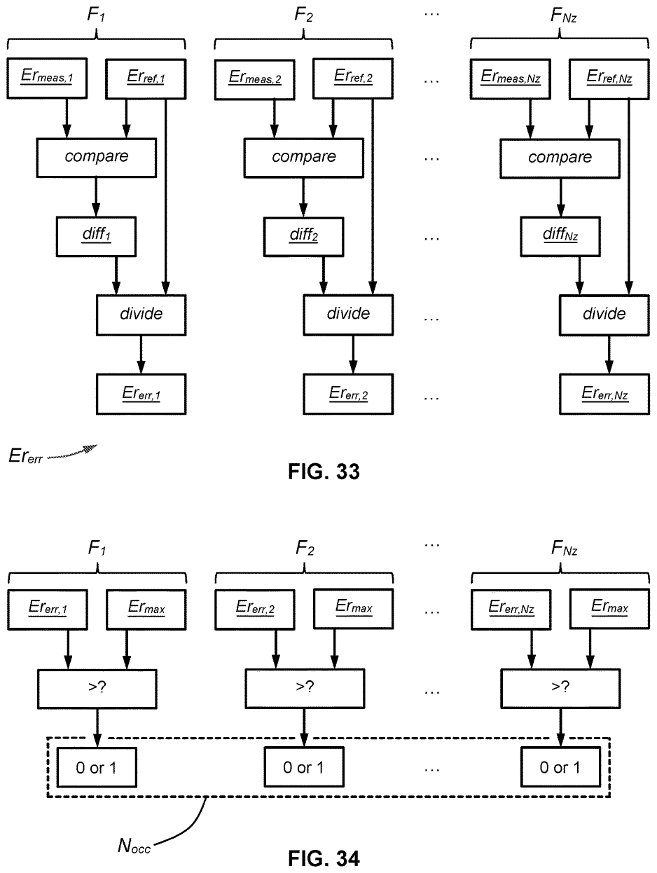

At block 240, a respective error of the errors Erₑᵣᵣ is calculated for each of the N_{z} pairs by dividing a difference between the respective measured impedance error Erₘₑₐₛ and the respective reference impedance error Er_{ref} by the respective reference impedance error Er_{ref}, thereby producing N_{z} respective errors of the errors Erₑᵣᵣ. This block 240 is further illustrated in FIG. 33, where calculations are shown for the first frequency point F₁, the second frequency point F₂ and through to the N_{z}^{th} frequency point F_{NZ}. For example, for the first frequency point F₁, the first measured impedance error Er_{meas,1} is compared with (e.g., subtracted from) the first reference impedance error Er_{ref,1}, which yields a first difference diff₁; this first difference diff₁ is then divided by the first reference impedance error Er_{ref,1}, which yields a first error of the errors Er_{err,1}. Similarly, for the second frequency point F₂, the second measured impedance error Er_{meas,2} is compared with (e.g., subtracted from) the second reference impedance error Er_{ref,2}, which yields a second difference diff₂; this second difference diff₂ is then divided by the second reference impedance error Er_{ref,2}, which yields a second error of the errors Er_{err,2}. And for the N_{z}^{th} frequency point F_{Nz}, the N_{z}^{th} measured impedance error Er_{meas,Nz} is compared with (e.g., subtracted from) N_{z}^{th} reference impedance error Er_{ref,Nz}, which yields N_{z}^{th} difference diff_{Nz}; this N_{z}^{th} difference diff_{Nz} is then divided by the N_{z}^{th} reference impedance error Er_{ref,Nz}, which yields N_{z}^{th} error of the errors Er_{err,Nz}.

At block 250, a number of occurrences N_{occ} is determined for when any one of the N_{z} errors of the errors Erₑᵣᵣ is greater than a maximum allowable error Erₘₐₓ. This block 250 is further illustrated in the block diagram of FIG. 34, where calculations are shown for the first frequency point F₁, the second frequency point F₂ and through to the N_{z}^{th} frequency point F_{NZ}. For example, for the first frequency point F₁, the first error of the errors Er_{err,1} is compared with the maximum allowable error Erₘₐₓ, which yields either a zero (0) if the first error of the errors Er_{err,1} is not greater than the maximum allowable error Erₘₐₓ, or a one (1) if the first error of the errors Er_{err,1} is greater than the maximum allowable error Erₘₐₓ. Similarly, for the second frequency point F₂, the second error of the errors Er_{err,2} is compared with the maximum allowable error Erₘₐₓ, which yields either a zero (0) if the second error of the errors Er_{err,2} is not greater than the maximum allowable error Erₘₐₓ or a one (1) if the second error of the errors Er_{err,2} is greater than the maximum allowable error Erₘₐₓ; and for the N_{z}^{th} frequency point F_{Nz}, the N_{z}^{th} error of the errors Er_{err,Nz} is compared with the maximum allowable error Erₘₐₓ, which yields either a zero (0) if the N_{z}^{th} error of the errors Er_{err,Nz} is not greater than the maximum allowable error Erₘₐₓ, or a one (1) if N_{z}^{th} error of the errors Er_{err,Nz} is greater than the maximum allowable error Erₘₐₓ. The number of occurrences N_{occ} is then the sum of these zeroes and ones.

And finally, at block 260, and as illustrated in the block diagram of FIG. 27, the battery B is identified as having a soft-short SS if the number of occurrences N_{occ} is greater than a threshold value N_{c}.

In this second algorithm or method 200, the main impedance Zₘ may be measured at a main temperature Tₘ, and the alternative impedance Zₐ may be measured an alternative temperature Tₐ, and in some cases, these impedances Zₘ, Zₐ may be measured at approximately the same temperature (i.e., Tₘ≈Tₐ).

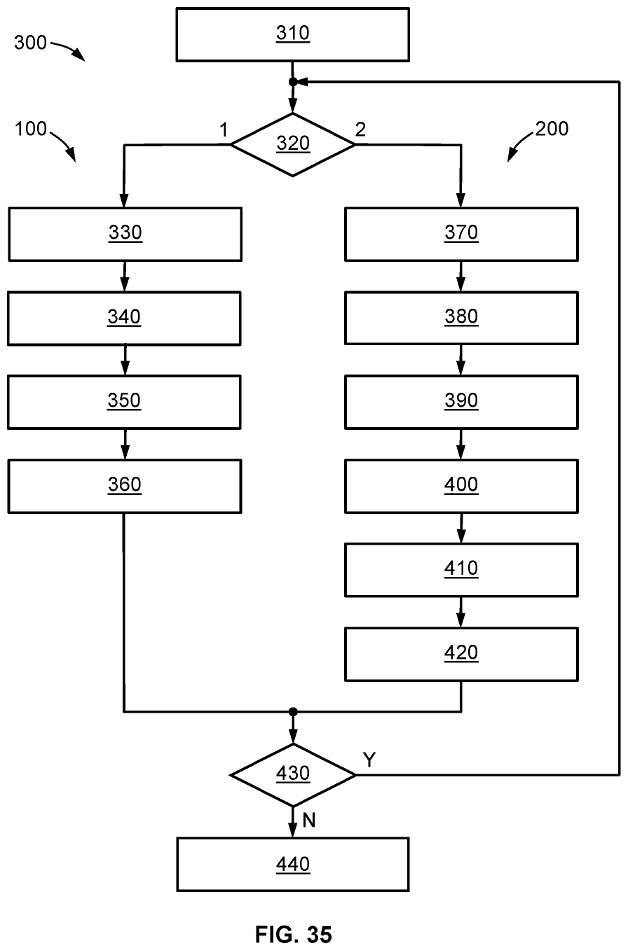

FIG. 35 shows a flowchart for the third algorithm or method 300, which may utilize elements found in one or both of the first and second algorithms 100, 200. This third algorithm or method 300 may be executed by the system 10 or by a vehicle VEH which has on-board capability for executing the third algorithm or method 300.

The third method 300 begins at a “START” at block 310, and at block 320 an evaluation or decision is made to execute the first algorithm 100 (via the branch labeled “1”) or the second algorithm 200 (via the branch labeled “2”).

The first algorithm 100 includes: (i) at block 330, measuring an impedance Z of the battery B at N_{z} frequency points within a frequency range FR and at a first voltage V₁ that is lower than a predetermined voltage level Vₚᵣₑ using the EIS system EIS, thereby producing N_{z} respective measured first impedances Z₁ each having a respective real component ReZ₁; (ii) at block 340, calculating a respective primary error Erₚ for each of the N_{z} measured first impedances Z₁ by comparing the respective real component ReZ₁ of each of the measured first impedances Z₁ with a respective first reference impedance Z_{ref1} that is representative of a healthy battery HB, thereby producing N_{z} respective primary errors Erₚ; (iii) at block 350, determining a number of occurrences N_{occ} of one of the N_{z} primary errors Erₚ being greater than a threshold error Er_{c}; and (iv) at block 360, identifying the battery B as having a soft-short SS if the number of occurrences N_{occ} is greater than a threshold value N_{c}.

The second algorithm 200 includes: (v) at block 370, measuring the impedance Z of the battery B at N_{z} frequency points within the frequency range FR and at respective second and third voltages V₂, V₃ that are each higher than the predetermined voltage level Vₚᵣₑ using the EIS system EIS, thereby producing N_{z} pairs of respective measured second and third impedances Z₂, Z₃ each having a respective real component ReZ₂, ReZ₃; (vi) at block 380, calculating a respective measured impedance error Erₘₑₐₛ for each of the N_{z} pairs by comparing the respective real component ReZ₂ of the respective measured second impedance Z₂ with the respective real component ReZ₃ of the respective measured third impedance Z₃, thereby producing N_{z} respective measured impedance errors Erₘₑₐₛ; (vii) at block 390, calculating a respective reference impedance error Er_{ref} for each of the N_{z} pairs by comparing a respective real component ReZ_{ref2} of a respective second reference impedance Z_{ref2} that corresponds to the second voltage V₂ with a respective real component ReZ_{ref3} of a respective third reference impedance Z_{ref3} that corresponds to the third voltage V₃, thereby producing N_{z} respective reference impedance errors Er_{ref}; (viii) at block 400, calculating a respective error of the errors Erₑᵣᵣ for each of the N_{z} pairs by dividing a difference between the respective measured impedance error Erₘₑₐₛ and the respective reference impedance error Er_{ref} by the respective reference impedance error Er_{ref}, thereby producing N_{z} respective errors of the errors Erₑᵣᵣ; (ix) at block 410, determining a number of occurrences N_{occ} of one of the N_{z} errors of the errors Erₑᵣᵣ being greater than a maximum allowable error Erₘₐₓ; and (x) at block 420, identifying the battery B as having a soft-short SS if the number of occurrences N_{occ} is greater than the threshold value N_{c}.

At block 430, an evaluation or decision is made whether to repeat the soft-short SS detection process; if yes (“Y”), the process flow returns to a point before block 320, but if no (“N”), the process flow advances to an “END” at block 440. Note that in this third method 300, the first and second algorithms 100, 200 may utilize the same frequency range FR, or they may utilize respective frequency ranges FR that are different from each other.

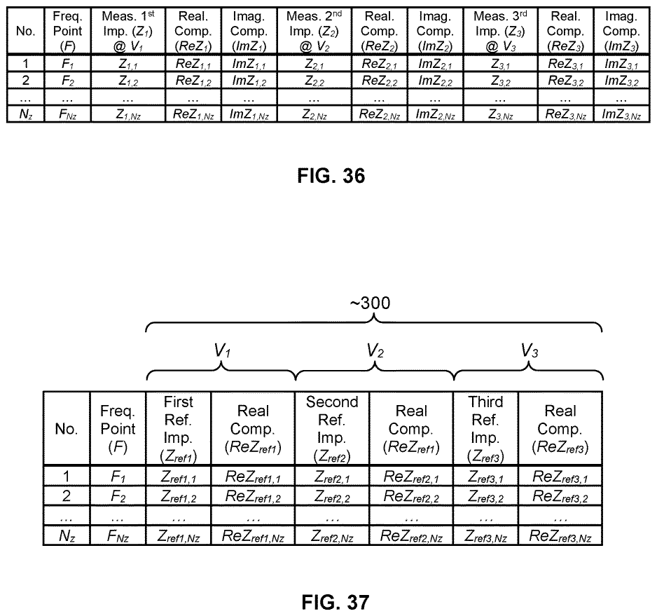

FIG. 36 shows a table of the various impedance measurements (and their respective real and imaginary components) which may be produced by the third algorithm or method 300, and FIG. 37 shows a table of reference impedances (and their respective real components) which may be used with the third algorithm or method 300. Various portions of these tables may be used during the process of executing the third algorithm or method 300, depending on whether the logic flow proceeds along the left-hand column of FIG. 35 (via the branch labeled “1”, corresponding to the first algorithm or method 100) or along the right-hand column of FIG. 35 (via the branch labeled “2”, corresponding to the second algorithm or method 200).

If the logic flow of the third algorithm or method 300 proceeds along the left-hand column of FIG. 35 (corresponding to the first algorithm or method 100), then at block 330, where the impedance Z of the battery B is measured at N_{z} frequency points F (i.e., at F₁, F₂, ... F_{Nz}) and at the first voltage V₁, the impedance values shown in the third, fourth and fifth columns of FIG. 36 are produced. For example, at the first voltage V₁, at the first frequency point F₁ the first measured impedance Z_{1,1} has corresponding real and imaginary components ReZ_{1,1}, ImZ_{1,1}, at the second frequency point F₂ the second measured impedance Z_{1,2} has corresponding real and imaginary components ReZ_{1,2}, ImZ_{1,2}, and at the N_{z}^{th} frequency point F_{Nz} the N_{z}^{th} measured impedance Z_{1,Nz} has corresponding real and imaginary components ReZ_{1,Nz}, ImZ_{1,Nz}.

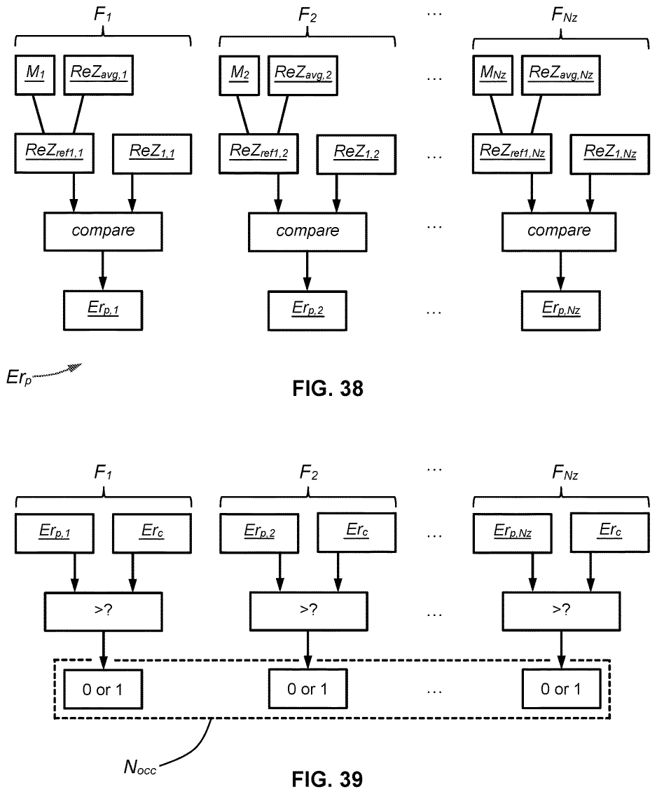

Next, at block 340, and as illustrated in the block diagram of FIG. 38, a respective primary error Erₚ is calculated for each of the N_{z} measured impedances Z₁ by comparing the respective real component ReZ₁ of each of the measured impedances Z₁ with a respective first reference impedance Z_{ref1} that is representative of a healthy battery HB, thereby producing N_{z} respective primary errors Erₚ.

In the table of FIG. 37, the first four columns illustrate the various instances of the first reference impedance Z_{ref1} which may be used for the N_{z} frequency points F. For the first frequency point F₁, the first instance of the first reference impedance Z_{ref1,1} has a first real component ReZ_{ref1,1} (and a corresponding imaginary component that is not shown). Similarly, for the second frequency point F₂, the second instance of the first reference impedance Z_{ref1,2} has a second real component ReZ_{ref1,2} (and a corresponding imaginary component that is not shown), and for the N_{z}^{th} frequency point F_{Nz}, the N_{z}^{th} instance of the first reference impedance Z_{ref1,Nz} has an N_{z}^{th} real component ReZ_{ref1,Nz} (and a corresponding imaginary component that is not shown).

Returning to FIG. 38, calculations are shown for block 340 for the first frequency point F₁, the second frequency point F₂ and through to the N_{z}^{th} frequency point F_{NZ}. For example, for the first frequency point F₁, the real component ReZ_{1,1} of the first measured impedance Z_{1,1} is compared with (e.g., subtracted from) the real component ReZ_{ref1,1} of the first instance of the first reference impedance Z_{ref1,1}, which yields a first primary error Er_{p,1}. Similarly, for the second frequency point F₂, the real component ReZ_{1,2} of the second measured impedance Z_{1,2} is compared with (e.g., subtracted from) the real component ReZ_{ref,2} of the second instance of the first reference impedance Z_{ref1,2}, which yields a second primary error Er_{p,2}, and for the N_{z}^{th} frequency point F_{Nz}, the real component ReZ_{1,Nz} of the N_{z}^{th} measured impedance Z_{1,Nz} is compared with (e.g., subtracted from) the real component ReZ_{ref1,Nz} of the N_{z}^{th} instance of the first reference impedance Z_{ref1,Nz}, which yields an N_{z}^{th} primary error Er_{p,Nz}.

Next, at block 350, a number of occurrences N_{occ} is determined of one of the N_{z} primary errors Erₚ being greater than a threshold error Er_{c}. This block 130 is further illustrated in the block diagram of FIG. 39, where calculations are shown for the first frequency point F₁, the second frequency point F₂ and through to the N_{z}^{th} frequency point F_{NZ}. For example, for the first frequency point F₁, the first primary error Er_{p,1} is compared with the threshold error Er_{c}, which yields either a zero (0) if the first primary error Er_{p,1} is not greater than the threshold error Er_{c}, or a one (1) if the first primary error Er_{p,1} is greater than the threshold error Er_{c}. Similarly, for the second frequency point F₂, the second primary error Er_{p,2} is compared with the threshold error Er_{c}, which yields either a zero (0) if the second primary error Er_{p,2} is not greater than the threshold error Er_{c} or a one (1) if the second primary error Er_{p,2} is greater than the threshold error Er_{c}; and for the N_{z}^{th} frequency point F_{Nz}, the N_{z}^{th} primary error Er_{p,Nz} is compared with the threshold error Er_{c}, which yields either a zero (0) if the N_{z}^{th} primary error Er_{p,Nz} is not greater than the threshold error Er_{c}, or a one (1) if the N_{z}^{th} primary error Er_{p,Nz} is greater than the threshold error Er_{c}. The number of occurrences N_{occ} is then the sum of these zeroes and ones.

Then, at block 360, and as illustrated in the block diagram of FIG. 27, the battery B is identified as having a soft-short SS if the number of occurrences N_{occ} is greater than a threshold value N_{c}.

On the other hand, if the logic flow of the third algorithm or method 300 proceeds along the right-hand column of FIG. 35 (corresponding to the second algorithm or method 200), then at block 370, the impedance Z of the battery B is measured at N_{z} frequency points within the frequency range FR and at the second and third voltages V₂, V₃ using the EIS system EIS, thereby producing N_{z} pairs of respective measured second and third impedances Z₂, Z₃. These pairs of second and third impedances Z₂, Z₃ are shown in the sixth through eleventh columns of FIG. 36. For example, at the second voltage V₂ (i.e., the sixth through eighth columns), at the first frequency point F₁ the first instance of the second measured impedance Z_{2,1} has corresponding real and imaginary components ReZ_{2,1}, ImZ_{2,1}, at the second frequency point F₂ the second instance of the second measured impedance Z_{2,2} has corresponding real and imaginary components ReZ_{2,2}, ImZ_{2,2}, and at the N_{z}^{th} frequency point F_{Nz} the N_{z}^{th} instance of the second measured impedance Z_{2,Nz} has corresponding real and imaginary components ReZ_{2,Nz}, ImZ_{2,Nz}. Similarly, at the third voltage V₃ (i.e., the ninth through eleventh columns), at the first frequency point F₁ the first instance of the third measured impedance Z_{3,1} has corresponding real and imaginary components ReZ_{3,1}, ImZ_{3,1}, at the second frequency point F₂ the second instance of the third measured impedance Z_{3,2} has corresponding real and imaginary components ReZ_{3,2}, ImZ_{3,2}, and at the N_{z}^{th} frequency point F_{Nz} the N_{z}^{th} instance of the third measured impedance Z_{3,Nz} has corresponding real and imaginary components ReZ_{3,Nz}, ImZ_{3,Nz}.

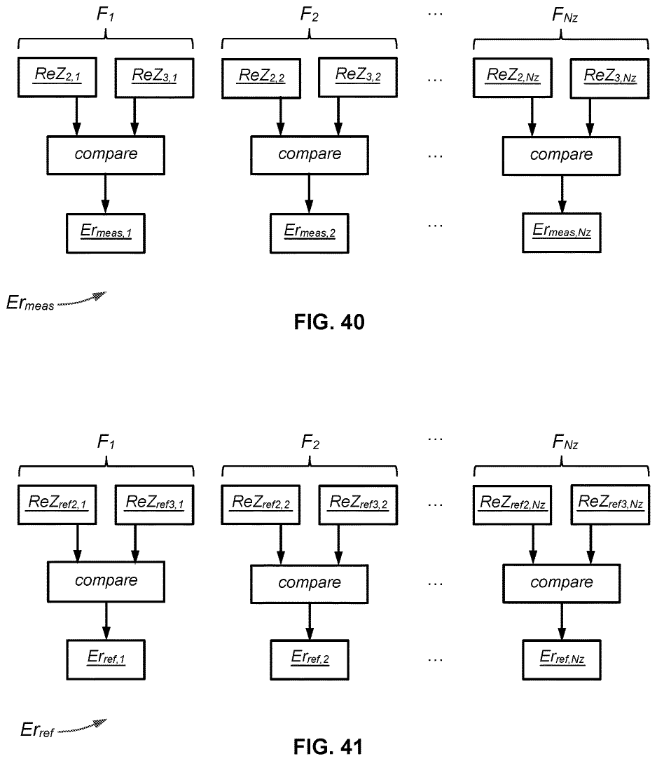

At block 380, a respective measured impedance error Erₘₑₐₛ is measured for each of the N_{z} pairs by comparing the respective real component ReZ₂ of the respective measured second impedance Z₂ with the respective real component ReZ₃ of the respective measured third impedance Z₃, thereby producing N_{z} respective measured impedance errors Erₘₑₐₛ. This block 380 is further illustrated in the block diagram of FIG. 40, where calculations are shown for the first frequency point F₁, the second frequency point F₂ and through to the N_{z}^{th} frequency point F_{NZ}. For example, for the first frequency point F₁, the real component ReZ_{2,1} of the first instance of the measured second impedance Z_{2,1} is compared with (e.g., subtracted from) the real component ReZ_{3,1} of the first instance of the measured third impedance Z_{3,1}, which yields a first measured impedance error Er_{meas,1}. Similarly, for the second frequency point F₂, the real component ReZ_{2,2} of the second instance of the measured second impedance Z_{2,2} is compared with (e.g., subtracted from) the real component ReZ_{3,2} of the second instance of the measured third impedance Z_{3,2}, which yields a second measured impedance error Er_{meas,2}; and for the N_{z}^{th} frequency point F_{Nz}, the real component ReZ_{2,Nz} of the N_{z}^{th} instance of the measured second impedance Z_{2,Nz} is compared with (e.g., subtracted from) the real component ReZ_{3,Nz} of the N_{z}^{th} instance of the measured third impedance Z_{3,Nz}, which yields an N_{z}^{th} measured impedance error Er_{meas,Nz}.

At block 390, a respective reference impedance error Er_{ref} is calculated for each of the N_{z} pairs by comparing a respective real component ReZ_{ref2} of a respective second reference impedance Z_{ref2} that corresponds to the second voltage V₂ with a respective real component ReZ_{ref3} of a respective third reference impedance Z_{ref3} that corresponds to the third voltage V₃, thereby producing N_{z} respective reference impedance errors Er_{ref}. This block 390 is further illustrated in the block diagram of FIG. 41 and in the first, second and fifth through eighth columns of the table in FIG. 37. In FIG. 41, calculations are shown for the first frequency point F₁, the second frequency point F₂ and through to the N_{z}^{th} frequency point F_{NZ}. For example, for the first frequency point F₁, the real component ReZ_{ref2,1} of the first instance of the second reference impedance Z_{ref2,1} is compared with (e.g., subtracted from) the real component ReZ_{ref3,1} of the first instance of the third reference impedance Z_{ref3,1}, which yields a first reference impedance error Er_{ref,1}. Similarly, for the second frequency point F₂, the real component ReZ_{ref2,2} of the second instance of the second reference impedance Z_{ref2,2} is compared with (e.g., subtracted from) the real component ReZ_{ref3,2} of the second instance of the third reference impedance Z_{ref3,2}, which yields a second reference impedance error Er_{ref,2}, and for the N_{z}^{th} frequency point F_{Nz}, the real component ReZ_{ref2,Nz} of the N_{z}^{th} instance of the second reference impedance Z_{ref2,Nz} is compared with (e.g., subtracted from) the real component ReZ_{ref3,Nz} of the N_{z}^{th} instance of the third reference impedance Z_{ref3,Nz}, which yields an N_{z}^{th} reference impedance error Er_{ref,Nz}.

In the table of FIG. 37, the first, second and fifth through eighth columns relate to the reference impedances Z_{ref} which correspond to the second and third voltages V₂, V₃. For the first frequency point F₁, the first instance of the second reference impedance Z_{ref2,1} has a first real component ReZ_{ref2,1} (and a corresponding imaginary component that is not shown), and the first instance of the third reference impedance Z_{ref3,1} has a first real component ReZ_{ref3,1} (and a corresponding imaginary component that is not shown). Similarly, for the second frequency point F₂, the second instance of the second reference impedance Z_{ref2,2} has a second real component ReZ_{ref2,2} (and a corresponding imaginary component that is not shown) and the second instance of the third reference impedance Z_{ref3,2} has a second real component ReZ_{ref3,2} (and a corresponding imaginary component that is not shown); and for the N_{z}^{th} frequency point F_{Nz}, the N_{z}^{th} instance of the second reference impedance Z_{ref2,Nz} has an N_{z}^{th} real component ReZ_{ref2,Nz} (and a corresponding imaginary component that is not shown) and the N_{z}^{th} instance of the third reference impedance Z_{ref3,Nz} has an N_{z}^{th} real component ReZ_{ref3,Nz} (and a corresponding imaginary component that is not shown).

At block 400, a respective error of the errors Erₑᵣᵣ is calculated for each of the N_{z} pairs by dividing a difference between the respective measured impedance error Erₘₑₐₛ and the respective reference impedance error Er_{ref} by the respective reference impedance error Er_{ref}, thereby producing N_{z} respective errors of the errors Erₑᵣᵣ. This block 400 is further illustrated in FIG. 33, where calculations are shown for the first frequency point F₁, the second frequency point F₂ and through to the N_{z}^{th} frequency point F_{NZ}. For example, for the first frequency point F₁, the first measured impedance error Er_{meas,1} is compared with (e.g., subtracted from) the first reference impedance error Er_{ref,1}, which yields a first difference diff₁; this first difference diff₁ is then divided by the first reference impedance error Er_{ref,1}, which yields a first error of the errors Er_{err,1}. Similarly, for the second frequency point F₂, the second measured impedance error Er_{meas,2} is compared with (e.g., subtracted from) the second reference impedance error Er_{ref,2}, which yields a second difference diff₂; this second difference diff₂ is then divided by the second reference impedance error Er_{ref,2}, which yields a second error of the errors Er_{err,2}. And for the N_{z}^{th} frequency point F_{Nz}, the N_{z}^{th} measured impedance error Er_{meas,Nz} is compared with (e.g., subtracted from) N_{z}^{th} reference impedance error Er_{ref,Nz}, which yields N_{z}^{th} difference diff_{Nz}; this N_{z}^{th} difference diff_{Nz} is then divided by the N_{z}^{th} reference impedance error Er_{ref,Nz}, which yields an N_{z}^{th} error of the errors Er_{err,Nz}.

At block 410, a number of occurrences N_{occ} is determined of one of the N_{z} errors of the errors Erₑᵣᵣ being greater than a maximum allowable error Erₘₐₓ. This block 410 is further illustrated in the block diagram of FIG. 34, where calculations are shown for the first frequency point F₁, the second frequency point F₂ and through to the N_{z}^{th} frequency point F_{NZ}. For example, for the first frequency point F₁, the first error of the errors Er_{err,1} is compared with the maximum allowable error Erₘₐₓ, which yields either a zero (0) if the first error of the errors Er_{err,1} is not greater than the maximum allowable error Erₘₐₓ, or a one (1) if the first error of the errors Er_{err,1} is greater than the maximum allowable error Erₘₐₓ. Similarly, for the second frequency point F₂, the second error of the errors Er_{err,2} is compared with the maximum allowable error Erₘₐₓ, which yields either a zero (0) if the second error of the errors Er_{err,2} is not greater than the maximum allowable error Erₘₐₓ or a one (1) if the second error of the errors Er_{err,2} is greater than the maximum allowable error Erₘₐₓ; and for the N_{z}^{th} frequency point F_{Nz}, the N_{z}^{th} error of the errors Er_{err,Nz} is compared with the maximum allowable error Erₘₐₓ, which yields either a zero (0) if the N_{z}^{th} error of the errors Er_{err,Nz} is not greater than the maximum allowable error Erₘₐₓ, or a one (1) if the N_{z}^{th} error of the errors Er_{err,Nz} is greater than the maximum allowable error Erₘₐₓ. The number of occurrences N_{occ} is then the sum of these zeroes and ones.

Finally, at block 420, and as illustrated in the block diagram of FIG. 27, the battery B is identified as having a soft-short SS if the number of occurrences N_{occ} is greater than the threshold value N_{c}.

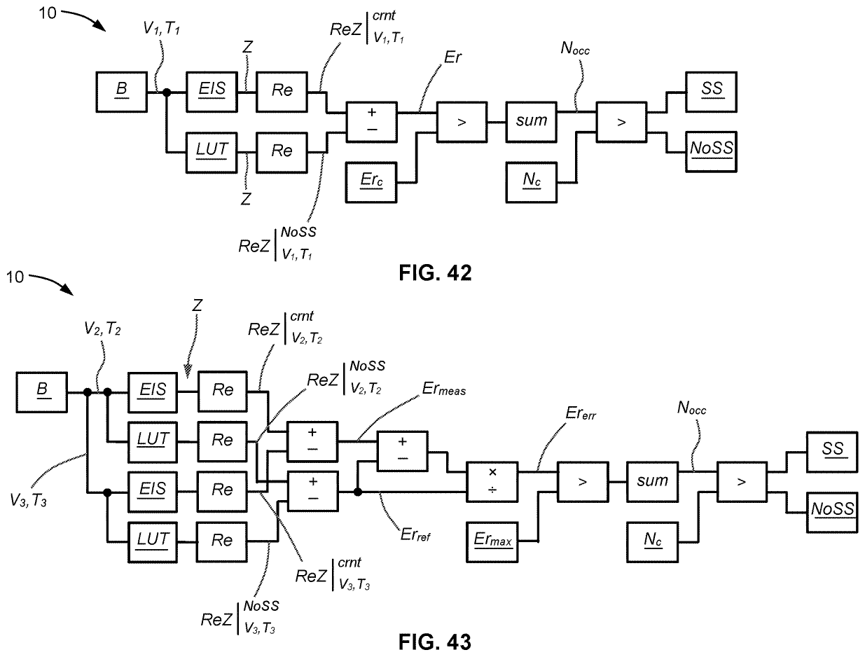

FIGS. 42-43 show logic flow diagrams for detecting a soft-short SS in a battery B according to the first and second algorithms/methods 100, 200, respectively. These diagrams may be used to design hardware, software and/or control systems or subsystems having the inputs, outputs, interconnections, sequences and logic components for executing the first and second algorithms/methods 100, 200.

In FIG. 42, a first voltage V₁ (e.g., lower than a predetermined voltage level Vₚᵣₑ) is sensed or accessed at a given temperature T₁ by an EIS system EIS and optionally by a look-up table LUT, and the impedance Z is measured at N_{z} frequency points F within a frequency range FR. The real components Re of these impedances Z are then extracted—see the ReZ|_{V1,T1}^{crnt} array which represents a collection of the current real components Re of these impedance measurements, and the ReZ|_{V1,T1}^{NoSS} array which represents a collection of stored/retrieved real components Re that are representative of a healthy battery HB with no soft-shorts SS (i.e., “NoSS”). These arrays or collections of data are compared with or subtracted from each other, resulting in N_{z} different calculated errors Er. These calculated errors Er are then compared against a threshold error Er_{c}, and a number of occurrences N_{occ} is determined as to how many of the N_{z} calculated errors Er are greater than the threshold error Er_{c}. If the number of occurrences N_{occ} is greater than a threshold value N_{c}, then a soft-short SS is deemed to have been detected; otherwise, a “no soft-short” (NoSS) condition is deemed to have been detected.

In FIG. 43, second and third voltages V₂, V₃ (e.g., both higher than a predetermined voltage level Vₚᵣₑ) are sensed or accessed at respective second and third temperatures T₂, T₃ by respective EIS systems EIS (or optionally by a single EIS system EIS) and also optionally sensed or accessed by respective look-up tables LUT, and the respective impedances Z are measured at N_{z} frequency points F within a frequency range FR. The real components Re of these impedances Z are then extracted—see the ReZ|_{V2,T2}^{crnt} and ReZ|_{V3,T3}^{crnt} arrays which represent respective collections of the current real components Re of these impedance measurements at the two voltages V₁, V₂, and the ReZ|_{V2,T2}^{NoSS} and ReZ|_{V3,T3}^{NoSS} arrays which represent a collection of stored/retrieved real components Re that are representative of a healthy battery HB with no soft-shorts SS (i.e., “NoSS”). The real components Re of the impedance measurements from the EIS system(s) EIS are compared with or subtracted from each other, resulting in N_{z} different measured impedance errors Erₘₑₐₛ, and the real components Re that are retrieved from the look-up tables LUT are compared with or subtracted from each other, resulting in N_{z} different reference impedance errors Er_{ref}. These measured impedance errors Erₘₑₐₛ and reference impedance errors Er_{ref} are compared with or subtracted from each other, and their differences are divided by the respective reference impedance errors Er_{ref}, resulting in N_{z} different errors of the errors Erₑᵣᵣ. These errors of the errors Erₑᵣᵣ are then compared against a maximum allowable error Erₘₐₓ, and a number of occurrences N_{occ} is determined as to how many of the N_{z} errors of the errors Erₑᵣᵣ are greater than the maximum allowable error Erₘₐₓ. If the number of occurrences N_{occ} is greater than a threshold value N_{c}, then a soft-short SS is deemed to have been detected; otherwise, a “no soft-short” (NoSS) condition is deemed to have been detected.

As one having skill in the relevant art will appreciate, the system 10, vehicle VEH and methods 100, 200, 300 of the present disclosure may be presented or arranged in a variety of different configurations and embodiments.

According to one embodiment, a method 100 for detecting a soft-short SS in a battery B includes: (i) at block 110, measuring an impedance Z of the battery B at N_{z} frequency points within a frequency range FR and at a selected voltage V₁ that is lower than a predetermined voltage level Vₚᵣₑ, thereby producing N_{z} respective measured impedances Z₁ each having a respective real component ReZ₁; (ii) at block 120, calculating a respective error Er for each of the N_{z} measured impedances Z₁ by comparing the respective real component ReZ₁ of each of the measured impedances Z₁ with a respective reference impedance Z_{ref} that is representative of a healthy battery HB, thereby producing N_{z} respective calculated errors Er; (iii) at block 130, determining a number of occurrences N_{occ} of one of the N_{z} calculated errors Er being greater than a threshold error Er_{c}; and (iv) at block 140, identifying the battery B as having a soft-short SS if the number of occurrences N_{occ} is greater than a threshold value N_{c}.

The measuring of the impedance Z at the N_{z} frequency points may be conducted using electrochemical impedance spectroscopy, and the frequency range FR may be approximately 0.01 to 1 Hz.

Each reference impedance Z_{ref} may be: (i) an average real impedance component ReZ_{avg} that is a proxy for the healthy battery HB; or (ii) a respective member M of a set S of real impedance components ReZ that are representative of the healthy battery HB. The average real impedance component ReZ_{avg} may be obtained from an average of respective real components of respective impedances from two or more other batteries OB that are configured for use with the battery B as measured at the selected voltage V₁ and within the frequency range FR. Each respective member M of the set S of real impedance components ReZ may correspond to a respective one of the N_{z} frequency points.

Each reference impedance Z_{ref} may be obtained from a look-up table LUT, and each of the measured impedances Z₁ may have a respective imaginary component ImZ₁.

The predetermined voltage level Vₚᵣₑ may be defined as a voltage level below which the real component of the measured impedance for a soft-shorted battery SSB differs substantially from the real component of the reference impedance for a healthy battery HB within the frequency range FR.

The impedance Z of the battery B may be measured at the N_{z} frequency points at approximately the same temperature T.

The battery B may be a lithium ion battery LIB, wherein the predetermined voltage level Vₚᵣₑ is approximately 3.5 volts.

According to another embodiment, a method 200 for detecting a soft-short SS in a battery B includes: (i) at block 210, measuring an impedance Z of the battery B at N_{z} frequency points within a frequency range FR and at respective main and alternative voltages Vₘ, Vₐ that are each higher than a predetermined voltage level Vₚᵣₑ, thereby producing N_{z} pairs of respective measured main and alternative impedances Zₘ, Zₐ each having a respective real component ReZₘ, ReZₐ; (ii) at block 220, calculating a respective measured impedance error Erₘₑₐₛ for each of the N_{z} pairs by comparing the respective real component ReZₘ of the respective measured main impedance Zₘ with the respective real component ReZₐ of the respective measured alternative impedance Zₐ, thereby producing N_{z} respective measured impedance errors Erₘₑₐₛ; (iii) at block 230, calculating a respective reference impedance error Er_{ref} for each of the N_{z} pairs by comparing a respective real component ReZ_{m-ref} of a respective main reference impedance Z_{m-ref} that corresponds to the main voltage Vₘ with a respective real component ReZ_{a-ref} of a respective alternative reference impedance Z_{a-ref} that corresponds to the alternative voltage Vₐ, thereby producing N_{z} respective reference impedance errors Er_{ref}; (iv) at block 240, calculating a respective error of the errors Erₑᵣᵣ for each of the N_{z} pairs by dividing a difference between the respective measured impedance error Erₘₑₐₛ and the respective reference impedance error Er_{ref} by the respective reference impedance error Er_{ref}, thereby producing N_{z} respective errors of the errors Erₑᵣᵣ; (v) at block 250, determining a number of occurrences N_{occ} of one of the N_{z} errors of the errors Erₑᵣᵣ being greater than a maximum allowable error Erₘₐₓ; and (vi) at block 260, identifying the battery B as having a soft-short SS if the number of occurrences N_{occ} is greater than a threshold value N_{c}.

In this embodiment, the measuring of the impedance Z at the N_{z} frequency points may be conducted using electrochemical impedance spectroscopy, and the frequency range FR may be approximately 0.1 to 10 Hz.

At least one of the main and alternative reference impedances Z_{m-ref}, Z_{a-ref} may be: (i) an average real impedance component ReZ_{avg} that is a proxy for a healthy battery HB; or (ii) a respective member M of a set S of real impedance components ReZ that are representative of the healthy battery HB. The average real impedance component ReZ_{avg} may be obtained from an average of respective real components of respective impedances from two or more other batteries OB that are configured for use with the battery B, and each respective member M of the set S of real impedance components ReZ may correspond to a respective one of the N_{z} frequency points.

The predetermined voltage level Vₚᵣₑ may be defined as a voltage level below which the real component of the measured impedance for a soft-shorted battery SSB differs substantially from the real component of the reference impedance for a healthy battery HB within the frequency range FR.

The main and alternative impedances Zₘ, Zₐ may be measured at approximately the same temperature Tₘ≈Tₐ, and the battery B may be a lithium ion battery LIB, wherein the predetermined voltage level Vₚᵣₑ is approximately 3.5 volts.

According to yet another embodiment, a vehicle VEH having on-board capability for detecting a soft-short SS in a battery B includes a vehicle body VB operatively supporting a propulsion system PS, an electrical system ES, the battery B and an electrochemical impedance spectroscopy (EIS) system EIS, wherein the propulsion system PS, the battery B and the EIS system EIS are each operatively connected with the electrical system ES, and wherein the EIS system EIS is configured for executing at least one of a first algorithm 100 and a second algorithm 200. The first algorithm 100 includes: (i) at block 330, measuring an impedance Z of the battery B at N_{z} frequency points within a frequency range FR and at a first voltage V₁ that is lower than a predetermined voltage level Vₚᵣₑ using the EIS system EIS, thereby producing N_{z} respective measured first impedances Z₁ each having a respective real component ReZ₁; (ii) at block 340, calculating a respective primary error Erₚ for each of the N_{z} measured first impedances Z₁ by comparing the respective real component ReZ₁ of each of the measured first impedances Z₁ with a respective first reference impedance Z_{ref1} that is representative of a healthy battery HB, thereby producing N_{z} respective primary errors Erₚ; (iii) at block 350, determining a number of occurrences N_{occ} of one of the N_{z} primary errors Erₚ being greater than a threshold error Er_{c}; and (iv) at block 360, identifying the battery B as having a soft-short SS if the number of occurrences N_{occ} is greater than a threshold value N_{c}. The second algorithm 200 includes: (v) at block 370, measuring the impedance Z of the battery B at N_{z} frequency points within the frequency range FR and at respective second and third voltages V₂, V₃ that are each higher than the predetermined voltage level Vₚᵣₑ using the EIS system EIS, thereby producing N_{z} pairs of respective measured second and third impedances Z₂, Z₃ each having a respective real component ReZ₂, ReZ₃; (vi) at block 380, calculating a respective measured impedance error Erₘₑₐₛ for each of the N_{z} pairs by comparing the respective real component ReZ₂ of the respective measured second impedance Z₂ with the respective real component ReZ₃ of the respective measured third impedance Z₃, thereby producing N_{z} respective measured impedance errors Erₘₑₐₛ; (vii) at block 390, calculating a respective reference impedance error Er_{ref} for each of the N_{z} pairs by comparing a respective real component ReZ_{ref2} of a respective second reference impedance Z_{ref2} that corresponds to the second voltage V₂ with a respective real component ReZ_{ref3} of a respective third reference impedance Z_{ref3} that corresponds to the third voltage V₃, thereby producing N_{z} respective reference impedance errors Er_{ref}; (viii) at block 400, calculating a respective error of the errors Erₑᵣᵣ for each of the N_{z} pairs by dividing a difference between the respective measured impedance error Erₘₑₐₛ and the respective reference impedance error Er_{ref} by the respective reference impedance error Er_{ref}, thereby producing N_{z} respective errors of the errors Erₑᵣᵣ; (ix) at block 410, determining a number of occurrences N_{occ} of one of the N_{z} errors of the errors Erₑᵣᵣ being greater than a maximum allowable error Erₘₐₓ; and (x) at block 420, identifying the battery B as having a soft-short SS if the number of occurrences N_{occ} is greater than the threshold value N_{c}.

While various steps of the methods 100, 200, 300 have been described as being separate blocks, and various functions of the system 10 and vehicle VEH have been described as being separate modules or elements, it may be noted that two or more steps may be combined into fewer blocks, and two or more functions may be combined into fewer modules or elements. Similarly, some steps described as a single block may be separated into two or more blocks, and some functions described as a single module or element may be separated into two or more modules or elements. Additionally, the order of the steps or blocks described herein may be rearranged in one or more different orders, and the arrangement of the functions, modules and elements may be rearranged into one or more different arrangements.

(As used herein, a “module” may include hardware and/or software, including executable instructions, for receiving one or more inputs, processing the one or more inputs, and providing one or more corresponding outputs. Also note that at some points throughout the present disclosure, reference may be made to a singular input, output, element, etc., while at other points reference may be made to plural/multiple inputs, outputs, elements, etc. Thus, weight should not be given to whether the input(s), output(s), element(s), etc. are used in the singular or plural form at any particular point in the present disclosure, as the singular and plural uses of such words should be viewed as being interchangeable, unless the specific context dictates otherwise.)

The above description is intended to be illustrative, and not restrictive. While the dimensions and types of materials described herein are intended to be illustrative, they are by no means limiting and are exemplary embodiments. In the following claims, use of the terms “first”, “second”, “top”, “bottom”, etc. are used merely as labels, and are not intended to impose numerical or positional requirements on their objects. As used herein, an element or step recited in the singular and preceded by the word “a” or “an” should be understood as not excluding plural of such elements or steps, unless such exclusion is explicitly stated. Additionally, the phrase “at least one of A and B” and the phrase “A and/or B” should each be understood to mean “only A, only B, or both A and B”. Moreover, unless explicitly stated to the contrary, embodiments “comprising” or “having” an element or a plurality of elements having a particular property may include additional such elements not having that property. And when broadly descriptive adverbs such as “substantially” and “generally” are used herein to modify an adjective, these adverbs mean “mostly”, “mainly”, “for the most part”, “to a significant extent”, “to a large degree” and/or “at least 51 to 99% out of a possible extent of 100%”, and do not necessarily mean “perfectly”, “completely”, “strictly”, “entirely” or “100%”. Additionally, the word “proximate” may be used herein to describe the location of an object or portion thereof with respect to another object or portion thereof, and/or to describe the positional relationship of two objects or their respective portions thereof with respect to each other, and may mean “near”, “adjacent”, “close to”, “close by”, “at”or the like.

This written description uses examples, including the best mode, to enable those skilled in the art to make and use devices, systems and compositions of matter, and to perform methods, according to this disclosure. It is the following claims, including equivalents, which define the scope of the present disclosure.

What is claimed is:

1. A method for detecting a soft-short in a battery, comprising:
measuring an impedance of the battery at N_{z} frequency points within a frequency range and at a selected voltage that is lower than a predetermined voltage level, thereby producing N_{z} respective measured impedances each having a respective real component;
calculating a respective error for each of the N_{z} measured impedances by comparing the respective real component of each of the measured impedances with a respective reference impedance that is representative of a healthy battery, thereby producing N_{z} respective calculated errors;
determining a number of occurrences of one of the N_{z} calculated errors being greater than a threshold error; and
identifying the battery as having a soft-short if the number of occurrences is greater than a threshold value.

2. The method of claim 1, wherein the measuring of the impedance at the N_{z} frequency points is conducted using electrochemical impedance spectroscopy.

3. The method of claim 1, wherein the frequency range is approximately 0.01 to 1 Hz.

4. The method of claim 1, wherein each reference impedance is:
an average real impedance component that is a proxy for the healthy battery; or
a respective member of a set of real impedance components that are representative of the healthy battery.

5. The method of claim 4, wherein the average real impedance component is obtained from an average of respective real components of respective impedances from two or more other batteries that are configured for use with the battery as measured at the selected voltage and within the frequency range.

6. The method of claim 4, wherein each respective member of the set of real impedance components corresponds to a respective one of the N_{z} frequency points.

7. The method of claim 1, wherein each reference impedance is obtained from a look-up table.

8. The method of claim 1, wherein each of the measured impedances has a respective imaginary component.

9. The method of claim 1, wherein the predetermined voltage level is defined as a voltage level below which the real component of the measured impedance for a soft-shorted battery differs substantially from the real component of the reference impedance for a healthy battery within the frequency range.

10. The method of claim 1, wherein the impedance of the battery is measured at the N_{z} frequency points at approximately the same temperature.

11. The method of claim 1, wherein the battery is a lithium ion battery, and wherein the predetermined voltage level is approximately 3.5 volts.

12. A method for detecting a soft-short in a battery, comprising:
measuring an impedance of the battery at N_{z} frequency points within a frequency range and at respective main and alternative voltages that are each higher than a predetermined voltage level, thereby producing N_{z} pairs of respective measured main and alternative impedances each having a respective real component;
calculating a respective measured impedance error for each of the N_{z} pairs by comparing the respective real component of the respective measured main impedance with the respective real component of the respective measured alternative impedance, thereby producing N_{z} respective measured impedance errors;
calculating a respective reference impedance error for each of the N_{z} pairs by comparing a respective real component of a respective main reference impedance that corresponds to the main voltage with a respective real component of a respective alternative reference impedance that corresponds to the alternative voltage, thereby producing N_{z} respective reference impedance errors;
calculating a respective error of the errors for each of the N_{z} pairs by dividing a difference between the respective measured impedance error and the respective reference impedance error by the respective reference impedance error, thereby producing N_{z} respective errors of the errors;
determining a number of occurrences of one of the N_{z} errors of the errors being greater than a maximum allowable error; and
identifying the battery as having a soft-short if the number of occurrences is greater than a threshold value.

13. The method of claim 12, wherein the measuring of the impedance at the N_{z} frequency points is conducted using electrochemical impedance spectroscopy.

14. The method of claim 12, wherein the frequency range is approximately 0.01 to 10 Hz.

15. The method of claim 12, wherein at least one of the main and alternative reference impedances is:
an average real impedance component that is a proxy for a healthy battery; or
a respective member of a set of real impedance components that are representative of the healthy battery.

16. The method of claim 15, wherein the average real impedance component is obtained from an average of respective real components of respective impedances from two or more other batteries that are configured for use with the battery, and wherein each respective member of the set of real impedance components corresponds to a respective one of the N_{z} frequency points.

17. The method of claim 12, wherein the predetermined voltage level is defined as a voltage level below which the real component of the measured impedance for a soft-shorted battery differs substantially from the real component of the reference impedance for a healthy battery within the frequency range.

18. The method of claim 12, wherein the main and alternative impedances are measured at approximately the same temperature.

19. The method of claim 12, wherein the battery is a lithium ion battery, and wherein the predetermined voltage level is approximately 3.5 volts.

20. A vehicle having on-board capability for detecting a soft-short in a battery, comprising:
a vehicle body operatively supporting a propulsion system, an electrical system, the battery and an electrochemical impedance spectroscopy (EIS) system, wherein the propulsion system, the battery and the EIS system are each operatively connected with the electrical system, and wherein the EIS system is configured for executing at least one of a first algorithm and a second algorithm;
wherein the first algorithm comprises:
measuring an impedance of the battery at N_{z} frequency points within a frequency range and at a first voltage that is lower than a predetermined voltage level using the EIS system, thereby producing N_{z} respective measured first impedances each having a respective real component;
calculating a respective primary error for each of the N_{z} measured first impedances by comparing the respective real component of each of the measured first impedances with a respective first reference impedance that is representative of a healthy battery, thereby producing N_{z} respective primary errors;
determining a number of occurrences of one of the N_{z} primary errors being greater than a threshold error; and
identifying the battery as having a soft-short if the number of occurrences is greater than a threshold value; and
wherein the second algorithm comprises:
measuring the impedance of the battery at N_{z} frequency points within the frequency range and at respective second and third voltages that are each higher than the predetermined voltage level using the EIS system, thereby producing N_{z} pairs of respective measured second and third impedances each having a respective real component;
calculating a respective measured impedance error for each of the N_{z} pairs by comparing the respective real component of the respective measured second impedance with the respective real component of the respective measured third impedance, thereby producing N_{z} respective measured impedance errors;
calculating a respective reference impedance error for each of the N_{z} pairs by comparing a respective real component of a respective second reference impedance that corresponds to the second voltage with a respective real component of a respective third reference impedance that corresponds to the third voltage, thereby producing N_{z} respective reference impedance errors;
calculating a respective error of the errors for each of the N_{z} pairs by dividing a difference between the respective measured impedance error and the respective reference impedance error by the respective reference impedance error, thereby producing N_{z} respective errors of the errors;
determining a number of occurrences of one of the N_{z} errors of the errors being greater than a maximum allowable error; and
identifying the battery as having a soft-short if the number of occurrences is greater than the threshold value.
